(19) United States
(12) Patent Application Publication
(10) Pub. No.: US 2026/0197987 A1
(43) Pub. Date: Jul. 9, 2026

(54) SEMICONDUCTOR DEVICES

(71) Applicant: SAMSUNG ELECTRONICS CO., LTD., Suwon-si (KR)

(72) Inventors: Hyunjin LEE, Suwon-si (KR); Minju KANG, Suwon-si (KR); Sujin KANG, Suwon-si (KR); Minsoo KIM, Suwon-si (KR); Yongkwan KIM, Suwon-si (KR); Huijung KIM, Suwon-si (KR); Heejae CHAE, Suwon-si (KR); Jaehyun CHOI, Suwon-si (KR)

(73) Assignee: SAMSUNG ELECTRONICS CO., LTD., Suwon-si (KR)

(21) Appl. No.: 19/442,344

(22) Filed: Jan. 7, 2026

(30) Foreign Application Priority Data
Jan. 8, 2025 (KR) 10-2025-0003061

(51) Int. Cl. H10B 12/00

(52) U.S. Cl. CPC H10B 12/00

(57) ABSTRACT

A semiconductor device according to an example embodiment of the present disclosure may include: a lower channel pattern extending in a vertical direction; a lower gate electrode overlapping the lower channel pattern in a first horizontal direction; an upper channel pattern overlapping the lower channel pattern in the vertical direction; an upper gate electrode overlapping the upper channel pattern in the first horizontal direction; and a charge storage region extending in the vertical direction and contacting the upper channel pattern. The lower channel pattern may include a first source/drain region, a second source/drain region spaced apart from the first source/drain region in the vertical direction, and a channel region between the first source/drain region and the second source/drain region, and at least a portion of the charge storage region may overlap the lower channel pattern in a second horizontal direction, intersecting the first horizontal direction.

### CROSS-REFERENCE TO RELATED APPLICATION(S)

This application claims benefit of priority to Korean Patent Application No. 10-2025-0003061 filed on Jan. 8, 2025, in the Korean Intellectual Property Office, the disclosure of which is incorporated herein by reference in its entirety.

### BACKGROUND

The present disclosure relates to semiconductor devices.

As the demand for high performance, high speed, and/or multi-functionality of semiconductor devices increases, the integration of semiconductor devices has increased. In order to manufacture semiconductor devices with fine patterns in response to the trend toward high integration of semiconductor devices, it is required to implement patterns having fine widths or fine separation distances.

### SUMMARY

An aspect of the present disclosure is to provide a semiconductor device including bitlines shared by adjacent memory cells.

A semiconductor device according to example embodiments may include: a lower channel pattern extending in a vertical direction; a lower gate electrode overlapping the lower channel pattern in a first horizontal direction; an upper channel pattern overlapping the lower channel pattern in the vertical direction; an upper gate electrode overlapping the upper channel pattern in the first horizontal direction; and a charge storage region extending in the vertical direction and contacting the upper channel pattern. The lower channel pattern may include a first source/drain region, a second source/drain region spaced apart from the first source/drain region in the vertical direction, and a channel region between the first source/drain region and the second source/drain region, and at least a portion of the charge storage region may overlap the lower channel pattern in a second horizontal direction, intersecting the first horizontal direction.

A semiconductor device according to example embodiments may include: lower channel patterns extending in a vertical direction and spaced apart from each other in a first horizontal direction; a lower gate electrode adjacent to the lower channel patterns in a second horizontal direction, intersecting the first horizontal direction, and extending in the first horizontal direction; upper channel patterns overlapping the lower channel patterns in the vertical direction; an upper gate electrode adjacent to the upper channel patterns in the second horizontal direction and extending in the first horizontal direction; and charge storage regions extending in the vertical direction and contacting lower surfaces of the upper channel patterns. Lower portions of the charge storage regions are alternately disposed with the lower channel patterns in the first horizontal direction.

A semiconductor device according to example embodiments may include: a lower channel pattern extending in a vertical direction; a conductive structure in contact with a lower surface of the lower channel pattern; a lower gate electrode overlapping the lower channel pattern in a first horizontal direction; an upper channel pattern overlapping the lower channel pattern in the vertical direction; a bitline structure between the lower channel pattern and the upper channel pattern; an upper gate electrode overlapping the upper channel pattern in the first horizontal direction; a charge storage region extending in the vertical direction and contacting the upper channel pattern; a dielectric pattern between a lower portion of the charge storage region and the lower channel pattern; and a spacer structure between an upper portion of the charge storage region and the bitline structure. At least a portion of the charge storage region overlaps the lower channel pattern in a second horizontal direction, intersecting the first horizontal direction.

According to example embodiments of the technical concept of the present disclosure, a lower channel pattern and a lower gate electrode overlap an upper channel pattern and an upper gate electrode in a vertical direction, respectively, and the charge storage region overlaps the lower channel pattern in a horizontal direction, thereby reducing the size of the semiconductor device.

Advantages and effects of the present disclosure are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a conceptual circuit diagram of a memory cell of a semiconductor device according to an example embodiment;

FIG. 2 is a schematic perspective view of a semiconductor device according to an example embodiment;

FIG. 3 is a plan view of a semiconductor device according to an example embodiment;

FIG. 4 is vertical cross-sectional views taken along lines I-I′ and II-II′ of the semiconductor device illustrated in FIG. 3;

FIG. 5 is a vertical cross-sectional view taken along line III-III′ of the semiconductor device illustrated in FIG. 3;

FIGS. 6A, 6B, and 6C are partially enlarged views of the semiconductor device illustrated in FIG. 4;

FIGS. 7, 8, and 9 are vertical cross-sectional views of a semiconductor device according to example embodiments;

FIGS. 10A, 10B, 10C, 10D, and 10E are vertical cross-sectional views of a semiconductor device according to example embodiments;

FIGS. 11 and 12 are vertical cross-sectional views of a semiconductor device according to example embodiments;

FIG. 13 is a plan view of a semiconductor device according to an example embodiment;

FIG. 14 is vertical cross-sectional views taken along line IV-IV′ and line V-V′ of the semiconductor device illustrated in FIG. 13; and

FIGS. 15A, 15B, 16A, 16B, 17A, 17B, 18A, 18B, 19A, 19B, 20A, 20B, 21A, 21B, 22A, 22B, 22C, 23A, 23B, 23C, 24A, 24B, 24C, 25A, 25B, 26A, 26B, 27A, 27B, 28A, 28B, 29A, and 29B are plan views and vertical cross-sectional views illustrating a method of manufacturing a semiconductor device according to an example embodiment of the present disclosure according to a process sequence.

### DETAILED DESCRIPTION

Hereinafter, example embodiments of the present disclosure will be described with reference to the accompanying drawings.

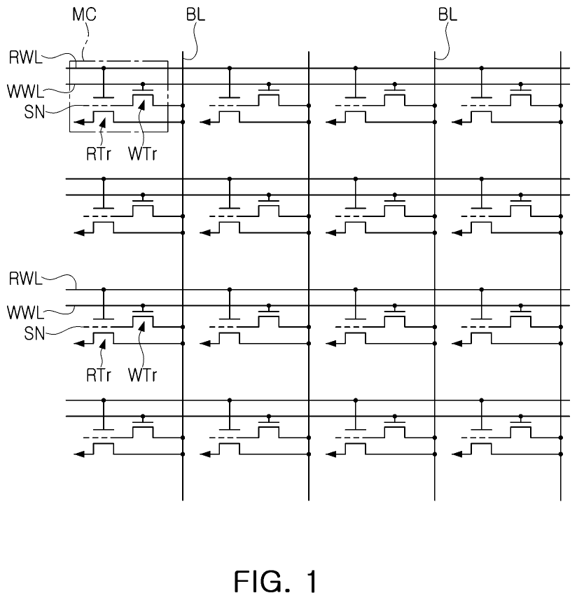

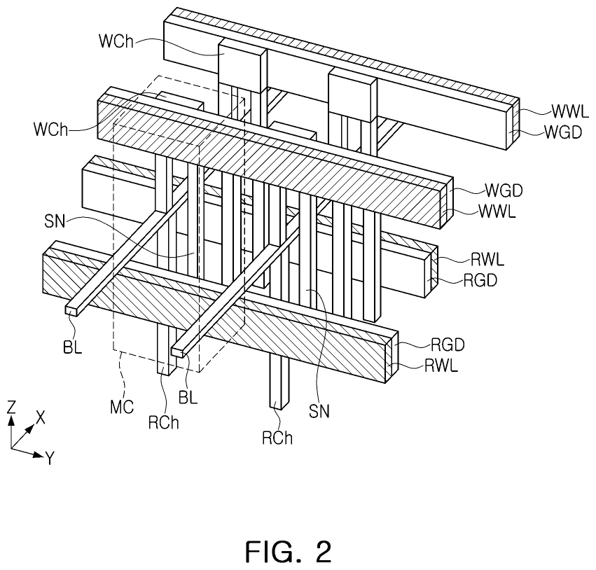

FIG. 1 is a conceptual circuit diagram of a memory cell of a semiconductor device according to an example embodiment. FIG. 2 is a schematic perspective view of a semiconductor device according to an example embodiment.

Referring to FIGS. 1 and 2, memory cells MC may be connected to bitlines BL and word lines WWL and RWL. Each memory cell MC may include a write transistor WTr, a read transistor RTr, and a storage node SN. Each of the write transistor WTr and the read transistor RTr may include a channel WCh and a channel RCh. The storage node SN may function as a gate (e.g., a floating gate) of the read transistor RTr, and may be electrically connected to the write transistor WTr. For example, the storage node SN may be electrically connected to the channel WCh of the write transistor WTr.

Each memory cell MC may be selected by the bitlines BL and the word lines WWL and RWL. Each of the memory cells MC may operate as a DRAM memory cell in which a write operation of storing information and a read operation of reading information are performed, and may not include a capacitor. For example, each of the memory cells MC may store information in the storage node SN instead of a capacitor, and may be referred to as a 2T memory cell.

The write transistor WTr may store charge in the storage node SN. Depending on the amount of charge stored in the storage node SN, a threshold voltage of the read transistor RTr in which the storage node SN functions as a gate may be changed. Depending on the threshold voltage of the read transistor RTr, information stored in the memory cell may be read as ‘0’ or ‘1.’

One end of a channel WCh of the write transistor WTr may be connected to a bitline BL, and the other end thereof may be connected to a storage node SN. A gate of the write transistor WTr may be electrically connected to a write word line WWL extending in a Y-direction. A write gate dielectric layer WGD may be disposed between the channels WCh of the write transistors WTr and the write word line WWL.

The channel RCh of the read transistor RTr may overlap the channel WCh of the write transistor WTr in a vertical direction (Z-direction). For example, the channel RCh of the read transistor RTr may be disposed below the channel WCh of the write transistor WTr. One end of the channel RCh of the read transistor RTr may be connected to the bitline BL, and the other end thereof may be grounded. A gate of the read transistor RTr may be electrically connected to a read word line RWL extending in the Y-direction. The storage node SN and the read word line RWL may be used for an on/off operation of the read transistor RTr. A read gate dielectric layer RGD may be disposed between the channels RCh of the read transistors RTr and the read word line RWL.

The bitline BL may be electrically connected to the memory cell MC. For example, the bitline BL may extend in an X-direction between the channel WCh of the write transistor WTr and the channel RCh of the read transistor RTr, and may be electrically connected to the channels WCh and RCh. In FIG. 1, the write word line WWL and the read word line RWL are illustrated as separate interconnection lines, but the present disclosure is not limited thereto. In an example embodiment, the write word line WWL may be electrically connected to the read word line RWL and may function as a single interconnection line.

According to example embodiments of the present disclosure, since the write word line WWL and the read word line RWL are disposed to overlap in the vertical direction, an area of the semiconductor device may be reduced and the integration of the memory cells MC may be increased, as compared to a case in which the write word line WWL and the read word line RWL are disposed on the same plane. Additionally, since the write word line WWL and the read word line RWL spaced apart from each other in the vertical direction may operate individually, the electrical characteristics of the write transistor WTr and the read transistor RTr may be improved.

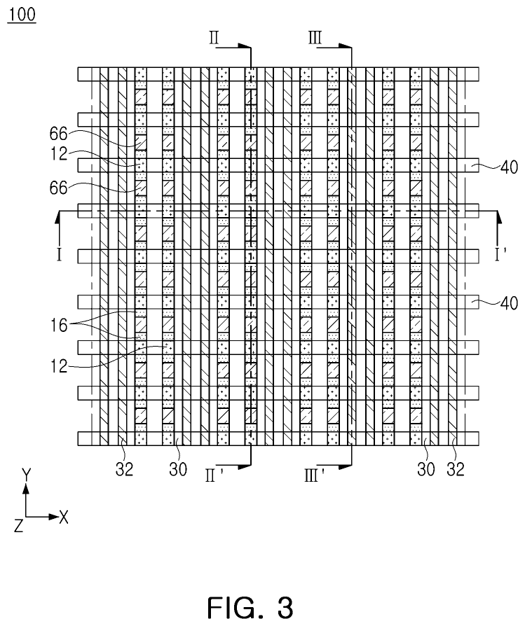

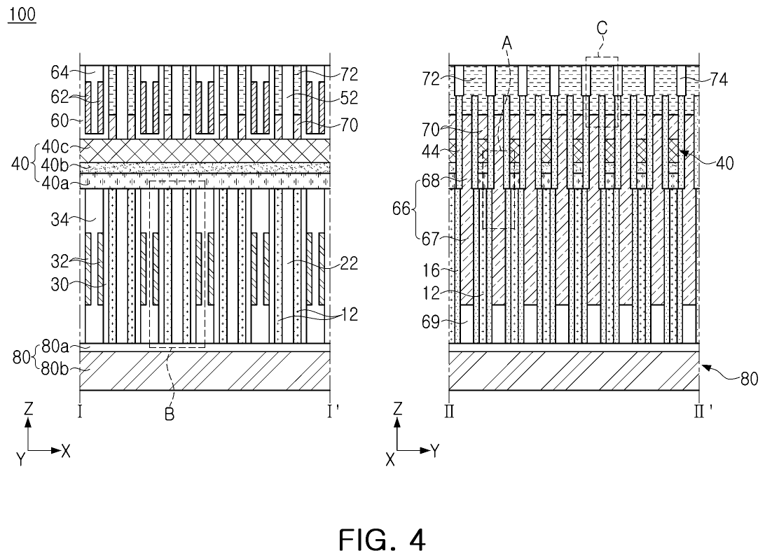

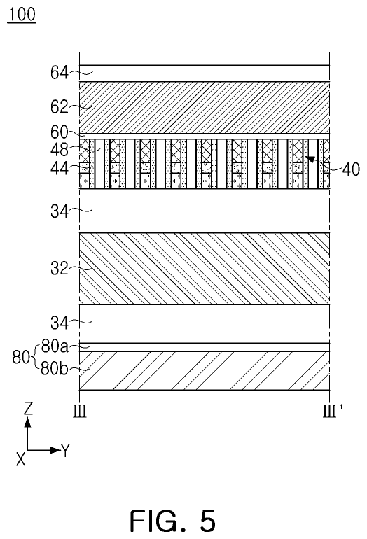

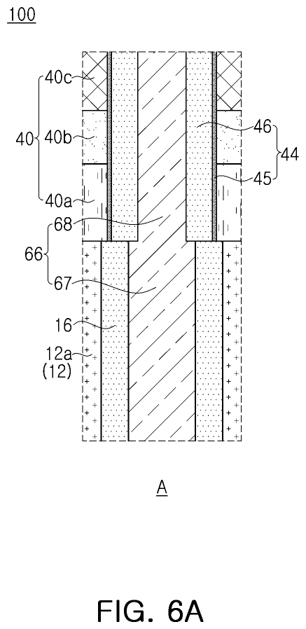

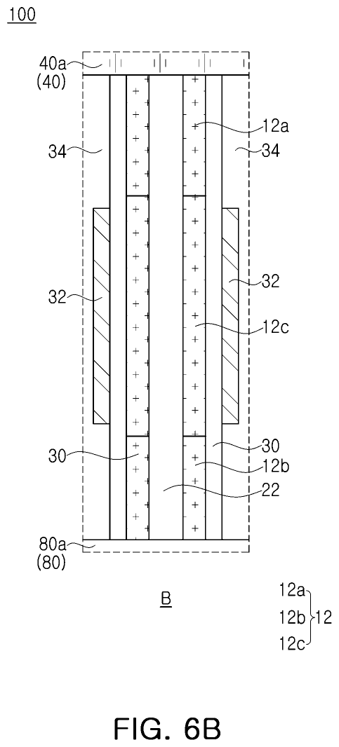

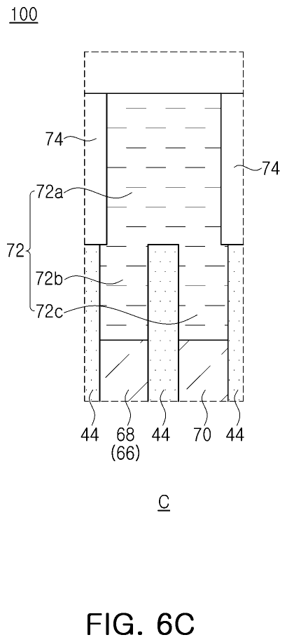

FIG. 3 is a plan view of a semiconductor device according to an example embodiment. FIG. 4 is vertical cross-sectional views along lines I-I′ and II-II′ of the semiconductor device illustrated in FIG. 3. FIG. 5 is a vertical cross-sectional view along line III-III′ of the semiconductor device illustrated in FIG. 3. FIGS. 6A to 6C are enlarged views of a portion of the semiconductor device illustrated in FIG. 4.

Referring to FIGS. 3 to 6C, a semiconductor device 100 according to an example embodiment of the present disclosure may include a lower channel pattern 12, a dielectric pattern 16, a lower gate dielectric layer 30, a lower gate electrode 32, a bitline structure 40, an upper gate dielectric layer 60, an upper gate electrode 62, a charge storage region 66, an upper channel pattern 72, and a conductive structure 80.

The write transistor WTr described with reference to FIGS. 1 and 2 may include an upper channel pattern 72. The upper channel pattern 72 may correspond to the channel WCh of FIG. 2, and the upper gate electrode 62 may correspond to the write word line WWL. The upper gate dielectric layer 60 may correspond to the write gate dielectric layer WGD. A portion of the upper gate electrode 62 overlapping the upper channel pattern 72 in the X-direction may function as the gate of the write transistor WTr. A portion of the upper gate dielectric layer 60 between the upper channel pattern 72 and the upper gate electrode 62 may be included in the write transistor WTr.

The read transistor RTr described with reference to FIGS. 1 and 2 may include a lower channel pattern 12. The lower channel pattern 12 may correspond to the channel RCh of FIG. 2, and the lower gate electrode 32 may correspond to the read word line RWL. The lower gate dielectric layer 30 may correspond to the read gate dielectric layer RGD. The charge storage region 66 may be electrically connected to the upper channel pattern 72, and may include the storage node SN described with reference to FIGS. 1 and 2. The charge storage region 66 may also function as a gate of a read transistor RTr. A portion of the dielectric pattern 16 between the lower channel pattern 12 and the charge storage region 66 may be included in the read transistor RTr.

The bitline structure 40 may be electrically connected to the lower channel pattern 12 and the upper channel pattern 72. The bitline structure 40 may include the bitline BL described with reference to FIGS. 1 and 2.

The lower channel pattern 12, the dielectric pattern 16, the lower gate dielectric layer 30, the lower gate electrode 32, the upper gate dielectric layer 60, the upper gate electrode 62, the charge storage region 66 and the upper channel pattern 72 may be included in the memory cell MC. The memory cells MC may have a structure identical to or similar to the memory cells MC described with reference to FIGS. 1 and 2.

The lower channel patterns 12 may extend in the vertical direction and may be spaced apart from each other in the X-direction and the Y-direction. The lower channel patterns 12 may include a semiconductor material, such as a group IV semiconductor, a group III-V compound semiconductor, or a group II-VI compound semiconductor. For example, the group IV semiconductor may include silicon, germanium, or silicon-germanium.

According to an example embodiment, the lower channel patterns 12 may include at least one of a polycrystalline semiconductor material, an oxide semiconductor material such as Indium Gallium Zinc Oxide (IGZO), or a two-dimensional material such as MoS₂. In an example embodiment, the lower channel patterns 12 may include an oxide semiconductor material.

In an example embodiment, the lower channel patterns 12 may include a single crystal semiconductor material such as single crystal silicon, and as illustrated in FIG. 6B, the lower channel patterns 12 may include a first source/drain region 12a, a second source/drain region 12b, and a channel region 12c. The first source/drain region 12a may be in contact with the bitline structure 40, and the second source/drain region 12b may be in contact with the conductive structure 80. The channel region 12c may be disposed between the first source/drain region 12a and the second source/drain region 12b. The first source/drain region 12a and the second source/drain region 12b are illustrated as not horizontally overlapping the lower gate electrode 32, but the present disclosure is not limited thereto. In an example embodiment, at least a portion of the first source/drain region 12a or the second source/drain region 12b may overlap the lower gate electrode 32 in a horizontal direction.

The first source/drain region 12a and the second source/drain region 12b may include impurities. In an example embodiment, when the read transistor RTr is an NMOS transistor, the first source/drain region 12a and the second source/drain region 12b may include N-type impurities, such as P or As. In an example embodiment, when the read transistor RTr is a PMOS transistor, the first source/drain region 12a and the second source/drain region 12b may include P-type impurities, such as B or Al.

The semiconductor device 100 may further include lower insulating patterns 22. The lower insulating patterns 22 may be disposed adjacently to the lower channel patterns 12. For example, two lower channel patterns 12 may be disposed between two lower insulating patterns 22 adjacent to each other in the X-direction. The lower channel patterns 12 may be in contact with both side surface of each of the lower insulating patterns 22, and the lower insulating patterns 22 may electrically insulate the lower channel patterns 12 from each other. The lower insulating patterns 22 may extend in the vertical direction, and for example, upper surfaces and lower surfaces of the lower insulating patterns 22 may be coplanar with upper surfaces and lower surfaces of the lower channel patterns 12, respectively. The lower insulating patterns 22 may extend in the Y-direction and may be spaced apart from each other in the X-direction.

The lower insulating patterns 22 may include silicon oxide, silicon nitride, silicon oxynitride, silicon carbonitride, a low-κ dielectric, or combinations thereof. For example, the lower insulating patterns 22 may include silicon oxide.

The lower gate electrodes 32 may extend in the Y-direction and may be spaced apart from each other in the X-direction. The lower gate electrodes 32 may be disposed adjacently to the lower channel patterns 12. For example, the lower gate electrodes 32 may overlap a portion of the lower channel patterns 12 in the X-direction. Two lower gate electrodes 32 may be disposed between two lower insulating patterns 22 adjacent to each other in the X-direction. A length of the lower gate electrodes 32 in the vertical direction may be smaller than the length of the lower channel patterns 12 along the vertical direction. For example, lower surfaces of the lower gate electrodes 32 may be disposed at a higher level than the lower surfaces of the lower channel patterns 12, and the upper surfaces of the lower gate electrodes 32 may be disposed at a lower level than upper surfaces of the lower channel patterns 12.

The lower gate electrodes 32 may include doped polysilicon, a metal, a conductive metal nitride, a metal-semiconductor compound, a metal compound, a conductive metal oxide, graphene, a carbon nanotube, or combinations thereof. For example, at least one of the lower gate electrodes 32 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotube, or combinations thereof.

The lower gate dielectric layers 30 may be disposed between the lower channel patterns 12 and the lower gate electrodes 32. For example, the lower gate dielectric layers 30 may be in contact with side surfaces of the lower channel patterns 12 facing adjacent lower gate electrodes 32, and may be in contact with side surfaces of the lower gate electrodes 32 facing adjacent lower channel patterns 12. The lower gate dielectric layers 30 may extend in the vertical direction, and for example, upper surface and lower surfaces of the lower gate dielectric layers 30 may be coplanar with the upper surfaces and the lower surfaces of the lower channel patterns 12, respectively. The lower gate dielectric layers 30 may extend in the Y-direction and may be spaced apart from each other in the X-direction.

Each of the lower gate dielectric layers 30 may include at least one of silicon oxide or a high-κ dielectric. For example, the high-κ dielectric may be formed of HfO₂, HfSiO, HfSiON, HfTaO, HfTiO, HfZrO, ZrO₂, Al₂O₃, or combinations thereof, but the present disclosure is not limited thereto. Each of the lower gate dielectric layers 30 may be formed of a single layer or multiple layers of the materials described above.

The semiconductor device 100 may further include lower capping layers 34. The lower capping layers 34 may cover the lower gate electrodes 32 adjacent to each other in the X-direction. For example, the lower capping layers 34 may cover the side surfaces, the lower surfaces and the upper surfaces of the lower gate electrodes 32, and may electrically insulate the lower gate electrodes 32 from each other. The lower capping layers 34 may also be in contact with the lower gate dielectric layers 30.

The lower capping layers 34 may include silicon oxide, silicon nitride, silicon oxynitride, silicon carbonitride, a low-κ dielectric, or combinations thereof. For example, the lower capping layers 34 may include silicon oxide. Each of the lower capping layers 34 is illustrated as a single layer, but the present disclosure is not limited thereto. In an example embodiment, each of the lower capping layers 34 may be formed of multiple layers.

The bitline structures 40 may be disposed on the lower channel patterns 12, and may be electrically connected to the lower channel patterns 12. The bitline structures 40 may extend in the X-direction, and may be spaced apart from each other in the Y-direction. Lower surfaces of the bitline structures 40 may be in contact with the lower channel patterns 12, the lower insulating patterns 22, the lower gate dielectric layers 30 and the lower capping layers 34.

The bitline structures 40 may include a conductive material, for example, doped single crystal silicon, doped polycrystalline silicon, a metal, a conductive metal nitride, a metal-semiconductor compound, a conductive metal oxide, conductive graphene, carbon nanotubes, or combinations thereof. In an example embodiment, the bitline structures 40 may include first to third conductive patterns 40a, 40b and 40c, which are sequentially stacked. For example, the first conductive pattern 40a may include doped polycrystalline silicon, the second conductive pattern 40b may include a silicide material, and the third conductive pattern 40c may include a metal. The first conductive pattern 40a may contact the first source/drain region 12a of the lower channel pattern 12. However, according to example embodiments, the number of layers and the type of material of the bitline structures 40 may be variously changed.

The charge storage regions 66 may be disposed between the lower channel patterns 12 and between the bitline structures 40. For example, in a plan view, the charge storage regions 66 may be spaced apart from the lower channel patterns 12 in the Y-direction and may be disposed alternately in the Y-direction. The charge storage regions 66 may extend in the vertical direction, and may be spaced apart from each other in the X-direction and the Y-direction. Lower surfaces of the charge storage regions 66 may be disposed at a higher level than the lower surfaces of the lower channel patterns 12, and upper surfaces of the charge storage regions 66 may be disposed at a higher level than upper surfaces of the bitline structures 40.

A portion of the charge storage regions 66, lower than the lower surface of the bitline structures 40, may be referred to as lower portions 67, and a portion of the charge storage regions 66, higher than the lower surface of the bitline structures 40, may be referred to as upper portions 68. The lower portions 67 may be disposed between the lower channel patterns 12, and the upper portions 68 may be disposed between the bitline structures 40. In an example embodiment, horizontal widths of the lower portions 67 may be different from horizontal widths of the upper portions 68. For example, as illustrated in FIG. 6A, the horizontal widths of the lower portions 67 may be greater than the horizontal widths of the upper portions 68.

The charge storage regions 66 may include a conductive material, for example, doped single crystal silicon, doped polycrystalline silicon, a metal, a conductive metal nitride, a metal-semiconductor compound, a conductive metal oxide, conductive graphene, a carbon nanotube, or combinations thereof. In an example embodiment, the charge storage regions 66 may include an oxide semiconductor, such as IGZO.

The semiconductor device 100 may further include spacer structures 44 and lower insulating layers 69. The spacer structures 44 may cover the side surfaces of the bitline structures 40, and may be disposed between the upper portions 68 of the charge storage regions 66 and the bitline structures 40. The spacer structures 44 may extend further above the upper surfaces of the bitline structures 40 and the charge storage regions 66. For example, upper ends of the spacer structures 44 may be disposed at a higher level than the upper surfaces of the bitline structures 40 and the charge storage regions 66.

In an example embodiment, each of the spacer structures 44 may include a first spacer 45 in contact with the bitline structures 40 and a second spacer 46 covering a side surface of the first spacer 45 and contacting the upper portions 68 of the charge storage regions 66. The spacer structures 44 may cover the side surfaces of the bitline structures 40 to prevent or reduce oxidation of the bitline structures 40 during the manufacturing process. The spacer structures 44 may include silicon oxide, silicon nitride, silicon oxynitride, silicon carbonitride, a low-κ dielectric, or combinations thereof. For example, the first spacers 45 may include silicon nitride, and the second spacers 46 may include silicon oxide.

The lower insulating layers 69 may be disposed below the charge storage regions 66. For example, the lower insulating layers 69 may be in contact the lower surfaces of the lower portions 67 of the charge storage regions 66. The lower insulating layers 69 may spatially and electrically isolate the charge storage regions 66 from the conductive structure 80. The lower insulating layers 69 may include silicon oxide, silicon nitride, silicon oxynitride, silicon carbonitride, a low-κ dielectric, or combinations thereof. For example, the lower insulating layers 69 may include silicon oxide.

The dielectric patterns 16 may be disposed between the lower channel patterns 12 and the charge storage regions 66. For example, the dielectric patterns 16 may be in contact with side surfaces of the lower channel patterns 12, perpendicular to the Y-direction, and may be in contact with the lower portions 67 of the charge storage regions 66 and the lower insulating layers 69. Upper surfaces of the dielectric patterns 16 may be coplanar with the upper surfaces of the lower channel patterns 12, and may be in contact with the spacer structures 44. Lower surfaces of the dielectric patterns 16 may be in contact with the conductive structure 80.

Each of the dielectric patterns 16 may include at least one of silicon oxide or a high-κ dielectric. Each of the dielectric patterns 16 may be formed as a single layer or multiple layers.

The semiconductor device 100 may further include upper conductive layers 70 disposed on the bitline structures 40. The upper conductive layers 70 may be in contact with the upper surfaces of the bitline structures 40, and may be in contact with side surfaces of the spacer structures 44. The upper conductive layers 70 may be alternately disposed in the Y-direction with the upper portions 68 of the charge storage regions 66. At least a portion of the upper conductive layers 70 may overlap the lower channel patterns 12 in the vertical direction, and the upper conductive layers 70 may be spaced apart from each other in the X-direction and the Y-direction.

The upper conductive layers 70 may electrically connect the bitline structures 40 to the upper channel patterns 72. In an example embodiment, upper surfaces of the upper conductive layers 70 may be disposed at the same level as upper surfaces of the upper portions 68 of the charge storage regions 66, but the present disclosure is not limited thereto. In an example embodiment, the upper conductive layers 70 may be formed simultaneously with the charge storage regions 66 and may include the same material as the charge storage regions 66.

The semiconductor device 100 may further include insulating structures 74. The insulating structures 74 may be disposed between the upper channel patterns 72. For example, the insulating structures 74 may extend from upper surfaces of the upper channel patterns 72 in the vertical direction and may be in contact with the spacer structures 44. The insulating structures 74 may be spaced apart from each other in the Y-direction, and may be disposed alternately in the Y-direction with the upper channel patterns 72. The insulating structures 74 may spatially and electrically isolate the upper channel patterns 72 from each other. The insulating structures 74 may include silicon oxide, silicon nitride, silicon oxynitride, silicon carbonitride, a low-κ dielectric, or combinations thereof. For example, the insulating structures 74 may include silicon oxide.

The upper channel patterns 72 may be in contact with and electrically connected to the charge storage regions 66. The upper channel patterns 72 may also be in contact with the upper conductive layers 70 and may be electrically connected to the bitline structures 40. As illustrated in FIG. 6C, each of the upper channel patterns 72 may include an upper portion 72a, a first lower portion 72b, and a second lower portion 72c. The upper portion 72a may be disposed at a higher level than that of a lower surface of the insulating structure 74, and the first lower portion 72b and the second lower portion 72c may be disposed at a lower level than that of the lower surface of the insulating structure 74. The upper portion 72a may be disposed on the first lower portion 72b and the second lower portion 72c, and may be disposed between the insulating structures 74.

The first lower portion 72b may overlap the charge storage region 66 in the vertical direction, and may be in contact with the upper portion 68 of the charge storage region 66. The second lower portion 72c may overlap the lower channel pattern 12 in the vertical direction, and may be in contact with the upper conductive layer 70. The first lower portion 72b may be spaced apart from the second lower portion 72c in the Y-direction with the spacer structure 44 interposed therebetween. The upper portion 72a, the first lower portion 72b and the second lower portion 72c may be formed integrally.

The upper channel patterns 72 may include a different material from the lower channel patterns 12. For example, the upper channel patterns 72 may include an oxide semiconductor material. The oxide semiconductor material may be indium gallium zinc oxide (IGZO). However, the example embodiment is not limited thereto. For example, the oxide semiconductor material may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), or indium gallium silicon oxide (InGaSiO).

The two-dimensional material may include at least one of a Transition Metal Dichalcogenide material layer (TMD material layer), a black phosphorous material layer, or a hexagonal Boron-Nitride material layer (hBN material layer), which may have semiconductor properties. For example, the two-dimensional material may include at least one of BiOSe, Crl, WSe₂, MoS₂, TaS, WS, SnSe, ReS, β-SnTe, MnO, AsS, P(black), InSe, h-BN, GaSe, GaN, SrTiO, MXene, or Janus 2D materials, which may form a two-dimensional material.

The semiconductor device 100 may further include upper insulating patterns 52. The upper insulating patterns 52 may be disposed adjacently to the upper channel patterns 72. For example, two upper channel patterns 72 may be disposed between two upper insulating patterns 52 adjacent to each other in the X-direction. The upper channel patterns 72 and upper conductive layers 70 may be in contact with both side surfaces of each upper insulating pattern 52. The upper insulating patterns 52 may extend in the vertical direction. For example, upper surfaces of the upper insulating patterns 52 may be coplanar with the upper surfaces of the upper channel patterns 72, and lower surfaces of the upper insulating patterns 52 may be coplanar with lower surfaces of the upper conductive layers 70. The upper insulating patterns 52 may extend in the Y-direction and be spaced apart from each other in the X-direction.

The upper insulating patterns 52 may include silicon oxide, silicon nitride, silicon oxynitride, silicon carbonitride, a low-κ dielectric, or combinations thereof. For example, the upper insulating patterns 52 may include silicon oxide.

The upper gate electrodes 62 may extend in the Y-direction and be spaced apart from each other in the X-direction. The upper gate electrodes 62 may be disposed adjacently to the upper channel patterns 72. For example, the upper gate electrodes 62 may overlap a portion of the upper channel patterns 72 in the X-direction. Two upper gate electrodes 62 may be disposed between two upper insulating patterns 52 adjacent to each other in the X-direction. Lower surfaces and upper surfaces of the upper gate electrodes 62 may be disposed at a lower level than that of lower surfaces and upper surfaces of the upper channel patterns 72, respectively. In an example embodiment, the upper gate electrodes 62 may overlap the upper portion 68 of the charge storage region 66 in the X-direction.

The upper gate electrodes 62 may include doped polysilicon, a metal, a conductive metal nitride, a metal-semiconductor compound, a metal compound, a conductive metal oxide, graphene, a carbon nanotube, or combinations thereof. For example, at least one of the upper gate electrodes 62 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotube, or combinations thereof.

The upper gate dielectric layers 60 may be disposed between the upper channel patterns 72 and the upper gate electrodes 62. For example, in a cross-sectional view, the upper gate dielectric layers 60 may have a U shape and may be in contact with side surfaces and lower surfaces of adjacent upper gate electrodes 62. The upper gate dielectric layers 60 may also be in contact with the bitline structures 40, the upper conductive layers 70, and the upper channel patterns 72. The upper gate dielectric layers 60 extend in the Y-direction and may be spaced apart from each other in the X-direction.

Each of the upper gate dielectric layers 60 may include at least one of silicon oxide or a high-κ dielectric. For example, the high-κ dielectric may be formed of HfO₂, HfSiO, HfSiON, HfTaO, HfTiO, HfZrO, ZrO₂, Al₂O₃, or combinations thereof, but the present disclosure is not limited thereto. Each of the upper gate dielectric layers 60 may be formed of a single layer or multiple layers of the materials described above.

The semiconductor device 100 may further include upper capping layers 64. The upper capping layers 64 may cover upper gate electrodes 62 adjacent to each other in the X-direction. For example, the upper capping layers 64 may cover side surfaces and upper surfaces of the upper gate electrodes 62, and may electrically insulate the upper gate electrodes 62 from each other. The upper capping layers 64 may also be in contact with the upper gate dielectric layers 60.

The upper capping layers 64 may include silicon oxide, silicon nitride, silicon oxynitride, silicon carbonitride, a low-κ dielectric, or combinations thereof. For example, the upper capping layers 64 may include silicon oxide. Each of the upper capping layers 64 may be formed of a single layer or multiple layers.

The semiconductor device 100 may further include upper sacrificial patterns 48. As illustrated in FIGS. 3 and 5, the upper sacrificial patterns 48 may vertically overlap the lower gate electrode 32 and the upper gate electrode 62, and may be disposed between the bitline structures 40. The upper sacrificial patterns 48 may include silicon oxide, silicon nitride, silicon oxynitride, silicon carbonitride, a low-κ dielectric, or combinations thereof. For example, the upper sacrificial patterns 48 may include silicon nitride.

The conductive structure 80 may be disposed below the lower channel patterns 12. For example, the conductive structure 80 may be in contact with the lower channel patterns 12, the dielectric patterns 16, the lower insulating patterns 22, the lower gate dielectric layers 30, the lower capping layers 34, and the lower insulating layers 69. The conductive structure 80 may be grounded. In an example embodiment, the conductive structure 80 may include a first conductive layer 80a in contact with the lower channel patterns 12 and a second conductive layer 80b below the first conductive layer 80a.

The conductive structure 80 may include a conductive material, and may include, for example, doped single-crystal silicon, doped polycrystalline silicon, a metal, a conductive metal nitride, a metal-semiconductor compound, a conductive metal oxide, conductive graphene, carbon nanotubes, or combinations thereof. For example, the first conductive layer 80a may include a silicide material, and the second conductive layer 80b may include a metal. However, according to example embodiments, the number of layers and the type of material of the bitline structures 40 may be variously changed. In an example embodiment, a conductive layer contacting the lower channel patterns 12 and including doped polycrystalline silicon may be further included on the first conductive layer 80a.

According to example embodiments of the present disclosure, the lower channel pattern 12 and the lower gate electrode 32 may overlap the upper channel pattern 72 and the upper gate electrode 62 in the vertical direction, respectively. Accordingly, the lower channel pattern 12 and the lower gate electrode 32 may reduce a horizontal size (an area in a plan view) of the semiconductor device 100, as compared to a case in which the lower channel pattern 12 and the lower gate electrode 32 are disposed at the same level as the upper channel pattern 72 and the upper gate electrode 62. Additionally, since the charge storage region 66 is disposed at the same level as the lower channel pattern 12, the horizontal size (an area in a plan view) of the semiconductor device 100 may be further reduced. Since the lower gate electrode 32 is spaced apart from the upper gate electrode 62 in the vertical direction, the lower gate electrode 32 and the upper gate electrode 62 may be controlled separately, respectively. Accordingly, the electrical characteristics of the read transistor RTr and the write transistor WTr may be improved.

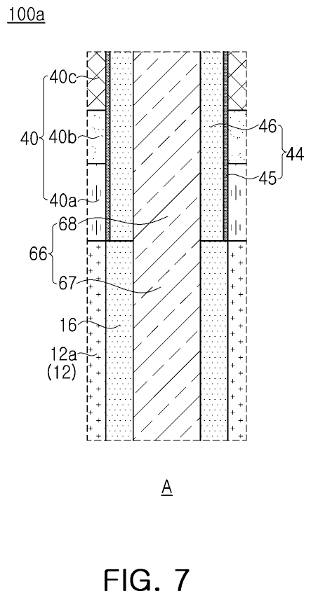

FIGS. 7 to 9 are vertical cross-sectional views of semiconductor devices according to example embodiments.

Referring to FIG. 7, a semiconductor device 100a may include a charge storage region 66 disposed between the lower channel patterns 12 and between the bitline structures 40. In an example embodiment, a horizontal width of the lower portion 67 of the charge storage region 66 may be the same as a horizontal width of the upper portion 68 of the charge storage region 66.

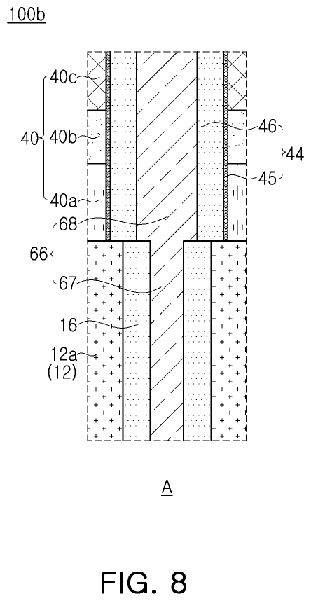

Referring to FIG. 8, a semiconductor device 100b may include a charge storage region 66 disposed between the lower channel patterns 12 and between the bitline structures 40. In an example embodiment, the horizontal width of the lower portion 67 of the charge storage region 66 may be different from the horizontal width of the upper portion 68. For example, the horizontal width of the lower portion 67 of the charge storage region 66 may be smaller than the horizontal width of the upper portion 68. An upper surface of the dielectric pattern 16 may be in contact with a lower surface of the upper portion 68 of the charge storage region 66.

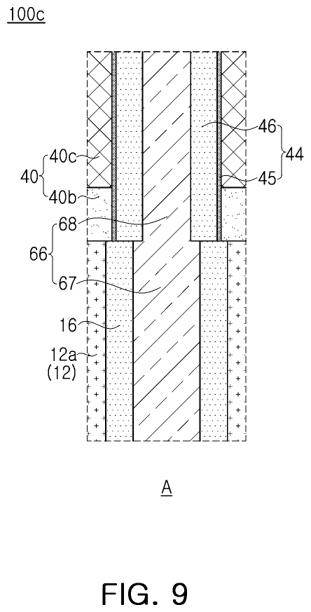

Referring to FIG. 9, a semiconductor device 100c may include a charge storage region 66 disposed between the lower channel patterns 12 and between the bitline structures 40. In an example embodiment, the first conductive patterns 40a of the bitline structures 40 may be omitted. For example, each of the bitline structures 40 may include a second conductive pattern 40b and a third conductive pattern 40c. The second conductive pattern 40b may be in contact with the first source/drain region 12a of the lower channel pattern 12.

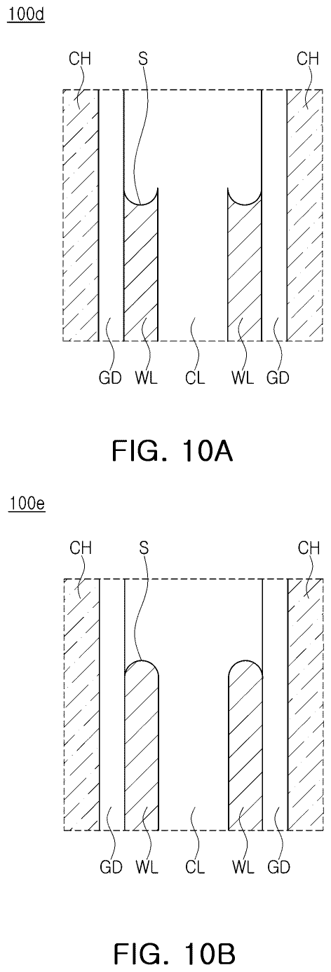

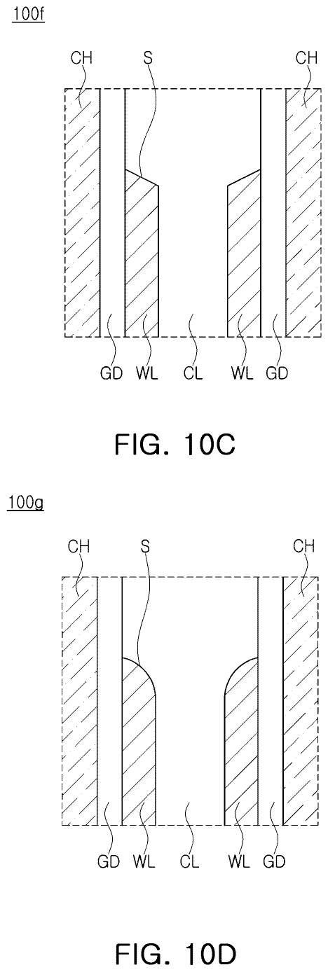

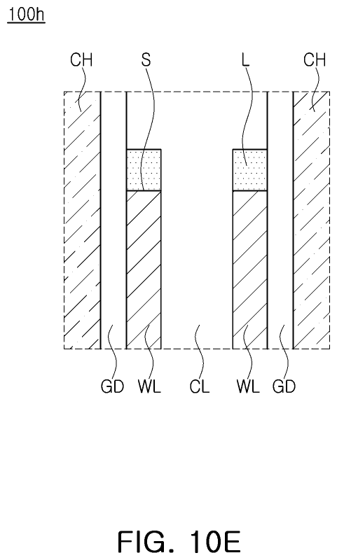

FIGS. 10A to 10E are vertical cross-sectional views of a semiconductor device according to example embodiments.

Each of the semiconductor devices 100d, 100e, 100f, 100g and 100h of FIGS. 10A to 10E may include a channel pattern CH, a gate electrode WL, a gate dielectric layer GD, and a capping layer CL. In an example embodiment, the channel pattern CH, the gate electrode WL, the gate dielectric layer GD, and the capping layer CL may correspond to the lower channel pattern 12, the lower gate electrode 32, the lower gate dielectric layer 30, and the lower capping layer 34, respectively. In an example embodiment, the channel pattern CH, the gate electrode WL, the gate dielectric layer GD, and the capping layer CL may correspond to the upper channel pattern 72, the upper gate electrode 62, the upper gate dielectric layer 60, and the upper capping layer 64, respectively. The semiconductor devices 100d, 100e, 100f and 100g of FIGS. 10A to 10D illustrates example embodiments in which a vertical length of the gate electrode WL varies according to a horizontal distance from a side surface of the channel pattern CH.

Referring to FIG. 10A, in an example embodiment, a surface S of the gate electrode WL of the semiconductor device 100d may be concave. In an example embodiment, the gate electrode WL may correspond to the lower gate electrode 32, and the surface S may correspond to at least one of the lower surface or the upper surface of the lower gate electrode 32. For example, at least one of the lower surface or the upper surface of the lower gate electrode 32 may be concave. In an example embodiment, the gate electrode WL may correspond to the upper gate electrode 62, and the surface S may correspond to an upper surface of the upper gate electrode 62. For example, the upper surface of the upper gate electrode 62 may be concave.

Referring to FIG. 10B, in an example embodiment, the surface S of the gate electrode WL of the semiconductor device 100e may be convex. In an example embodiment, the gate electrode WL may correspond to the lower gate electrode 32, and the surface S may correspond to at least one of the lower surface or the upper surface of the lower gate electrode 32. For example, at least one of the lower surface or the upper surface of the lower gate electrode 32 may be convex. In an example embodiment, the gate electrode WL may correspond to the upper gate electrode 62, and the surface S may correspond to the upper surface of the upper gate electrode 62. For example, the upper surface of the upper gate electrode 62 may be convex.

Referring to FIG. 10C, in an example embodiment, the surface S of the gate electrode WL of the semiconductor device 100f may be inclined with respect to a lower surface of the channel pattern CH. In an example embodiment, the gate electrode WL may correspond to the lower gate electrode 32, and the surface S may correspond to at least one of the lower surface or the upper surface of the lower gate electrode 32. For example, at least one of the lower surface or the upper surface of the lower gate electrode 32 may be inclined, and a vertical length of the lower gate electrode 32 may increase as the lower gate electrode 32 gets closer to the lower channel pattern 12. In an example embodiment, the gate electrode WL may correspond to the upper gate electrode 62, and the surface S may correspond to the upper surface of the upper gate electrode 62. For example, the upper surface of the upper gate electrode 62 may be inclined, and a vertical length of the upper gate electrode 62 may increase as the upper gate electrode 62 gets closer to the upper channel pattern 72.

Referring to FIG. 10D, in an example embodiment, the surface S of the gate electrode WL of the semiconductor device 100g may be rounded. In an example embodiment, the gate electrode WL may correspond to the lower gate electrode 32, and the surface S may correspond to at least one of the lower surface or the upper surface of the lower gate electrode 32. For example, at least one of the lower surface or the upper surface of the lower gate electrode 32 may be rounded, and the vertical length of the lower gate electrode 32 may increase as the lower gate electrode 32 gets closer to the lower channel pattern 12. In an example embodiment, the gate electrode WL may correspond to the upper gate electrode 62, and the surface S may correspond to the upper surface of the upper gate electrode 62. For example, the upper surface of the upper gate electrode 62 may be rounded, and the vertical length of the upper gate electrode 62 may increase as the upper gate electrode 62 gets closer to the upper channel pattern 72.

Referring to FIG. 10E, a semiconductor device 100h may further include a conductive layer L on the surface S of the gate electrode WL. The conductive layer L may be used to control a threshold voltage of the write transistor WTr or the read transistor RTr. For example, the conductive layer L may include a material different from the gate electrode WL, and may include a material having a work function different from that of the gate electrode WL. In an example embodiment, the conductive layer L may include at least one of a metal, a metal nitride, or polycrystalline silicon. For example, the conductive layer L may include at least one of Ti, Ta, W, TiN, TaN, WN, or polycrystalline silicon. The conductive layer L may further include a work function adjusting element, and the work function adjusting element may include at least one of La, Sr, Sb, Y, Al, Ta, Hf, Ir, Zr, or Mg.

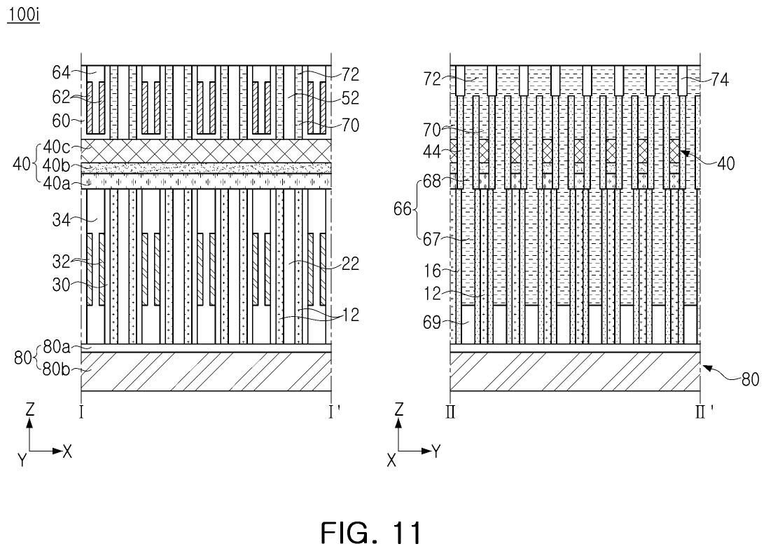

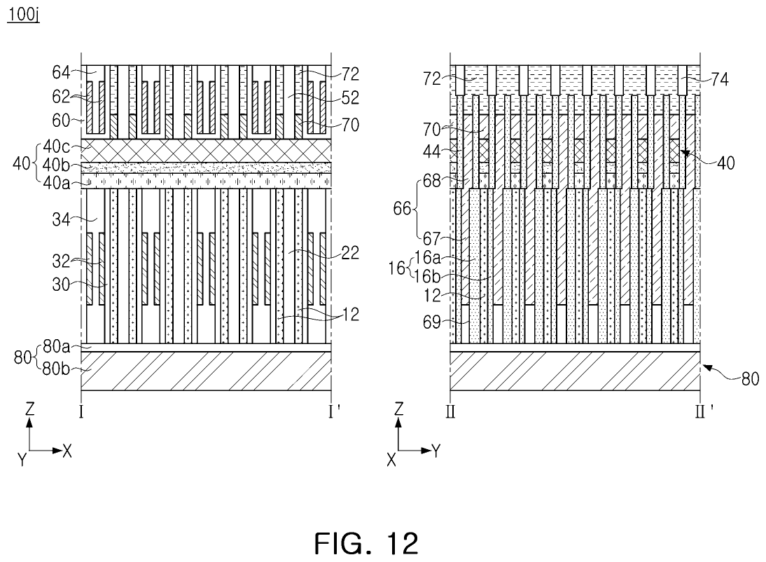

FIGS. 11 and 12 are vertical cross-sectional views of a semiconductor device according to example embodiments.

Referring to FIG. 11, the charge storage region 66, the upper conductive layer 70, and the upper channel pattern 72 of a semiconductor device 100i may include the same material and may be formed integrally. A boundary between the charge storage region 66 and the upper channel pattern 72 and a boundary between the upper conductive layer 70 and the upper channel pattern 72 may not be observed. For example, the charge storage region 66, the upper conductive layer 70, and the upper channel pattern 72 may include an oxide semiconductor material such as IGZO.

Referring to FIG. 12, each of the dielectric patterns 16 of a semiconductor device 100j may include a first dielectric pattern 16a and a second dielectric pattern 16b. The first dielectric pattern 16a and the second dielectric pattern 16b may be spaced apart from each other in the Y-direction with the lower channel pattern 12 interposed therebetween. For example, each of the lower channel patterns 12 may include a first side surface, perpendicular to the Y-direction, and a second side surface opposite to the first side surface. The first dielectric pattern 16a may be in contact with the first side surface, and the second dielectric pattern 16b may be in contact with the second side surface.

In an example embodiment, a horizontal width of the first dielectric pattern 16a in the Y-direction may be greater than a horizontal width of the second dielectric pattern 16b in the Y-direction. For example, for each lower channel pattern 12, distances between the lower channel pattern 12 and two adjacent charge storage regions 66 may be different. For each lower channel pattern 12, a distance between the charge storage region 66 in contact with the first dielectric pattern 16a and the lower channel pattern 12 may be greater than a distance between the charge storage region 66 in contact with the second dielectric pattern 16b and the lower channel pattern 12.

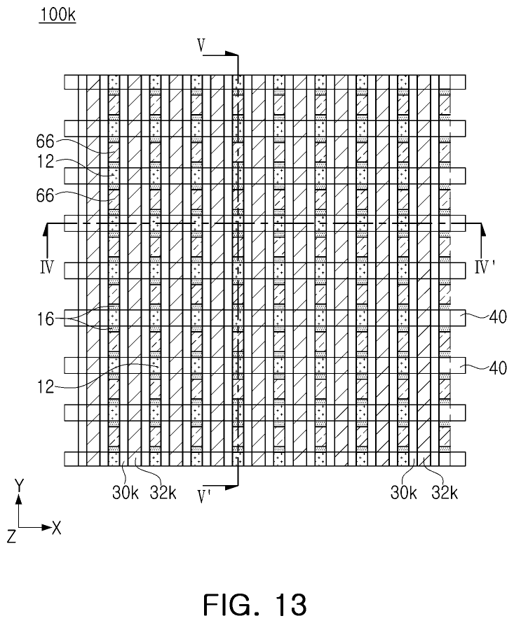

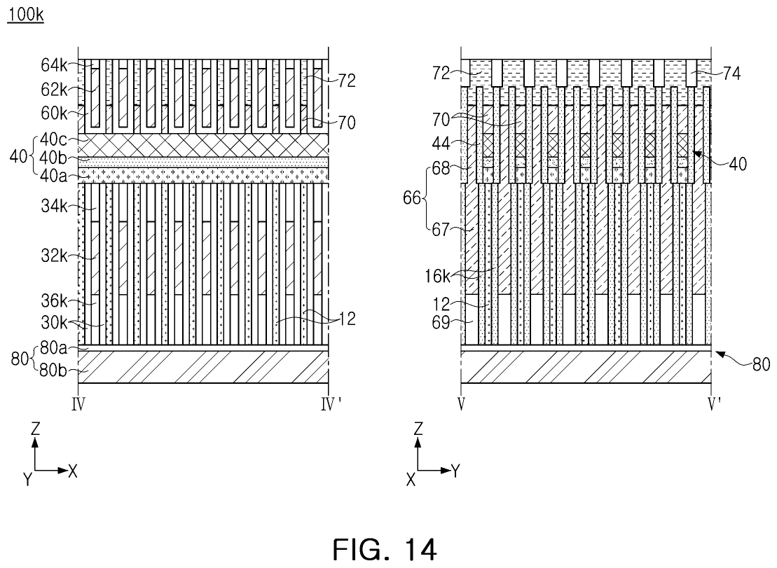

FIG. 13 is a plan view of a semiconductor device according to an example embodiment. FIG. 14 is vertical cross-sectional views taken along lines IV-IV′ and V-V′ of the semiconductor device illustrated in FIG. 13.

Referring to FIGS. 13 and 14, a semiconductor device 100k may include a dielectric pattern 16k, a lower gate dielectric layer 30k, a lower gate electrode 32k, a first lower capping layer 34k, and a second lower capping layer 36k. In an example embodiment, the lower insulating pattern 22 of the semiconductor device 100 may be omitted, and the lower gate electrodes 32k may be alternately disposed with the lower channel patterns 12 in the X-direction. The lower gate dielectric layers 30k may be in contact with side surfaces of each of the lower channel patterns 12 and side surfaces of each of the lower gate electrodes 32k. The first lower capping layers 34k may be disposed on the lower gate electrodes 32k, and the second lower capping layers 36k may be disposed below the lower gate electrodes 32k. The dielectric pattern 16k may cover a side surface of the lower channel pattern 12 and may be disposed between the lower channel pattern 12 and the charge storage region 66.

The semiconductor device 100k may include an upper gate dielectric layer 60k, an upper gate electrode 62k, and an upper capping layer 64k. In an example embodiment, the upper insulating pattern 52 of the semiconductor device 100 may be omitted, and the upper gate electrodes 62k may be disposed alternately with the upper channel patterns 72 in the X-direction. The upper gate dielectric layers 60k may cover lower surfaces and side surfaces of each of the upper gate electrodes 62k. The upper capping layers 64k may cover upper surfaces of the upper gate electrodes 62k.

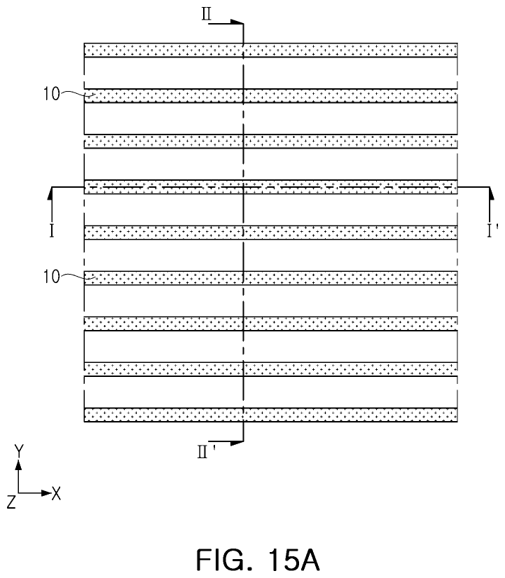

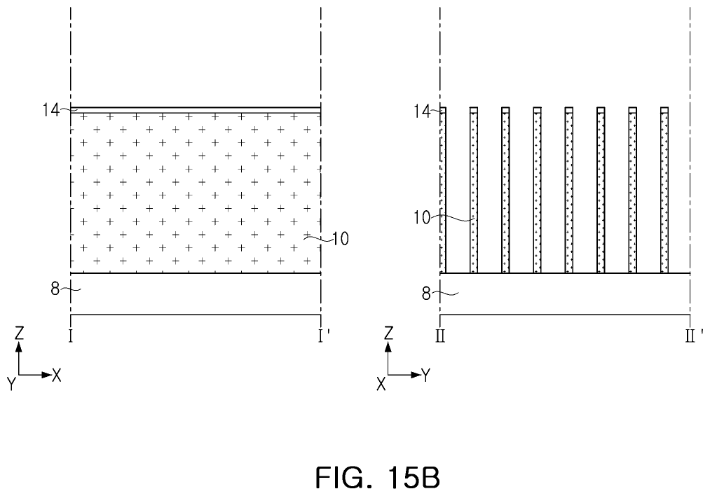

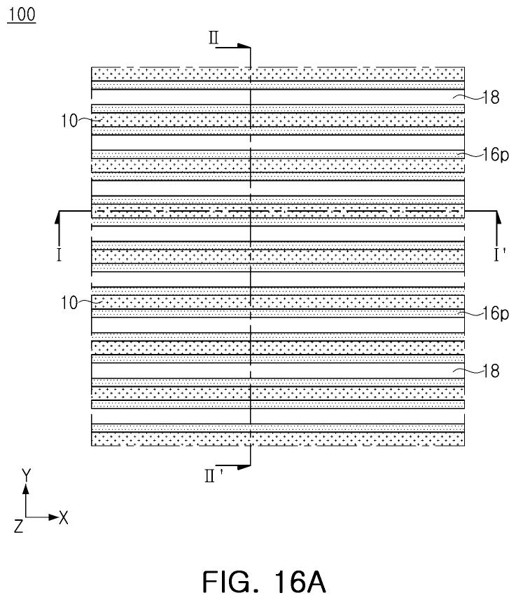

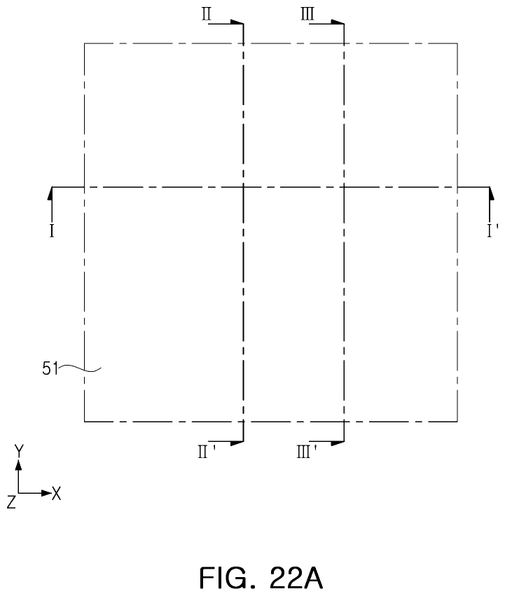

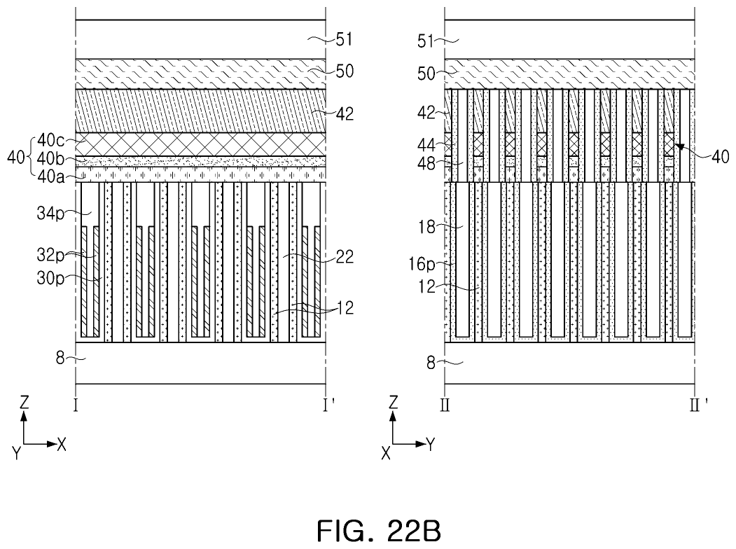

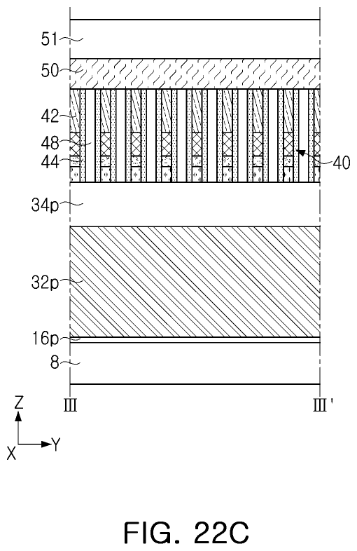

FIGS. 15A to 29B are plan views and vertical cross-sectional views illustrating a method of manufacturing a semiconductor device according to an example embodiment according to a process sequence. Specifically, FIGS. 15A, 16A, 17A, 18A, 19A, 20A, 21A, 22A, 23A, 24A, 25A, 26A, 27A and 28A are plan views corresponding to FIG. 3. FIGS. 15B, 16B, 17B, 18B, 19B, 20B, 21B, 22B, 23B, 24B, 25B, 26B, 27A, 28B and 29A are vertical cross-sectional views corresponding to FIG. 4. FIGS. 22C, 23C, 24C and 29B are vertical cross-sectional views corresponding to FIG. 5.

Referring to FIGS. 15A and 15B, mask layers 14 may be formed on substrates 8 and 10. The substrates 8 and 10 may include an insulating layer 8 and semiconductor patterns 10 on the insulating layer 8. In an example embodiment, the substrates 8 and 10 may be SOI substrates, and a semiconductor material layer may be further disposed below the insulating layer 8. In an example embodiment, the substrate may be a bulk silicon substrate, and the insulating layer 8 may be omitted.

The semiconductor patterns 10 may be formed by patterning a semiconductor material layer on the insulating layer 8. For example, mask layers 14 may be formed on the semiconductor material layer, and the semiconductor patterns 10 may be formed by an anisotropic etching process using the mask layers 14 as an etching mask. The mask layers 14 may cover upper surfaces of the semiconductor patterns 10. The semiconductor patterns 10 may extend in the X-direction and may be spaced apart from each other in the Y-direction. The semiconductor patterns 10 may include a semiconductor material, such as a group IV semiconductor, a group III-V compound semiconductor, or a group II-VI compound semiconductor.

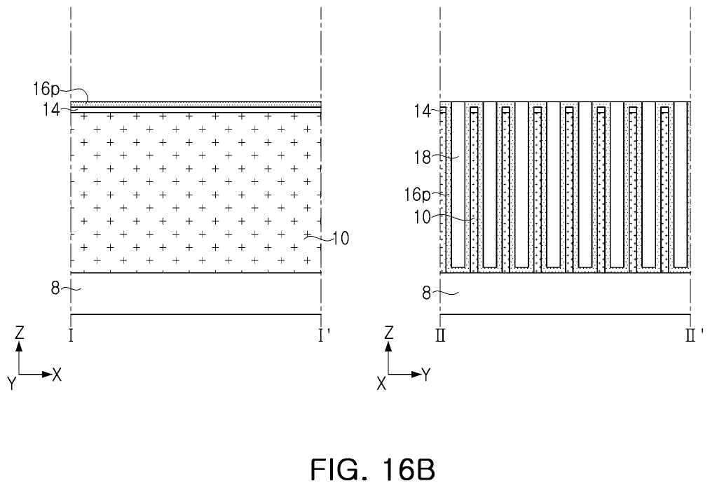

Referring to FIGS. 16A and 16B, a dielectric material layer 16p and lower sacrificial patterns 18 may be formed. The dielectric material layer 16p may conformally cover the insulating layer 8 and the semiconductor patterns 10. For example, the dielectric material layer 16p may cover an upper surface of the insulating layer 8 and side surfaces and upper surfaces of the semiconductor patterns 10. The lower sacrificial patterns 18 may be formed on the dielectric material layer 16p and may fill a space between the semiconductor patterns 10. The lower sacrificial patterns 18 may form a sacrificial material layer on the dielectric material layer 16p, and may be formed by removing an upper portion of the sacrificial material layer by a planarization process so that the dielectric material layer 16p is exposed. The lower sacrificial patterns 18 may extend in the X-direction and may be spaced apart from each other in the Y-direction.

The dielectric material layer 16p may include a dielectric material, and may include, for example, silicon oxide, but the present disclosure is not limited thereto. The lower sacrificial patterns 18 may include a material having an etching selectivity with the dielectric material layer 16p. For example, the lower sacrificial patterns 18 may include silicon nitride.

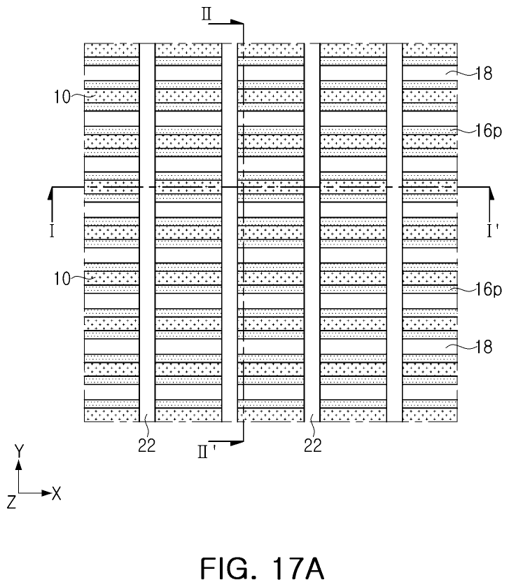

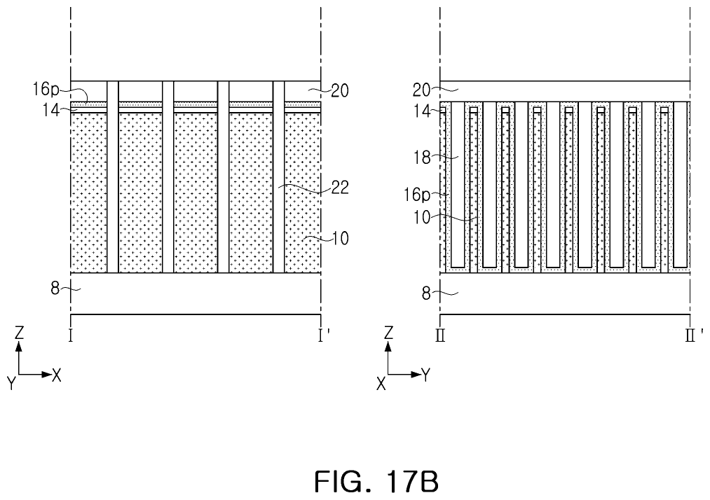

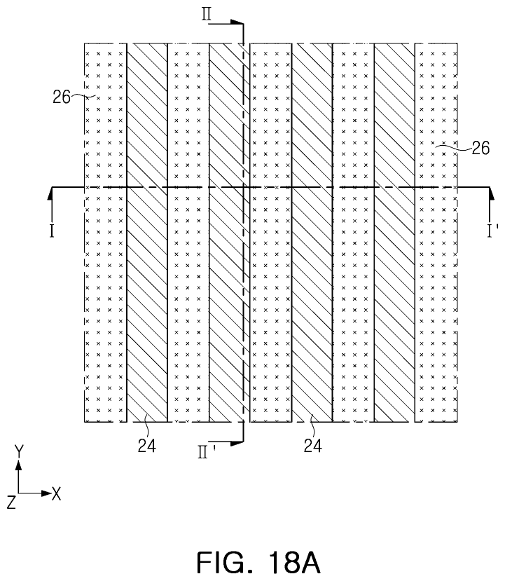

Referring to FIGS. 17A and 17B, a sacrificial layer 20 and lower insulating patterns 22 may be formed. The sacrificial layer 20 may cover the dielectric material layer 16p and the lower sacrificial patterns 18. The lower insulating patterns 22 may be formed by etching the semiconductor patterns 10, the mask layers 14, the dielectric material layer 16p, the lower sacrificial patterns 18 and the sacrificial layer 20 in an anisotropic etching process and then filling the etched portions with an insulating material. The lower insulating patterns 22 may protrude upwardly from the upper surfaces of the semiconductor patterns 10, and the lower surfaces of the lower insulating patterns 22 may be in contact with the insulating layer 8. The lower insulating patterns 22 may extend in the Y-direction and may be spaced apart from each other in the X-direction.

The lower insulating patterns 22 may include silicon oxide, silicon nitride, silicon oxynitride, silicon carbonitride, a low-κ dielectric, or combinations thereof. For example, the lower insulating patterns 22 may include silicon oxide. The sacrificial layer 20 may include a material having an etching selectivity with respect to the lower insulating patterns 22. For example, the sacrificial layer 20 may include silicon nitride.

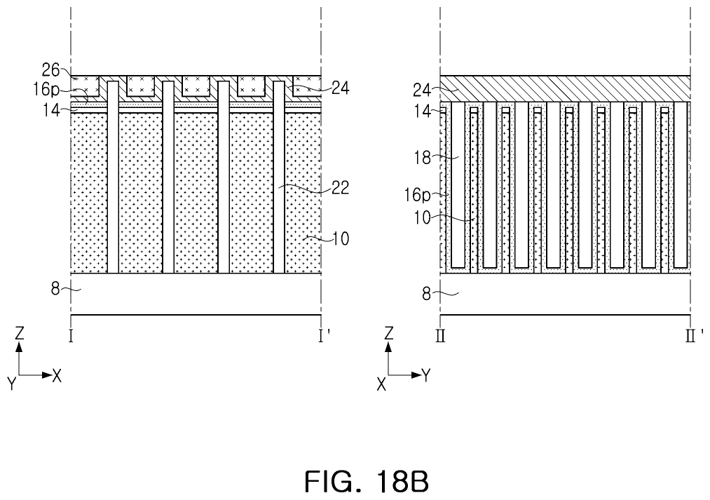

Referring to FIGS. 18A and 18B, the sacrificial layer 20 may be removed, and a first material layer 24 and the second material layers 26 may be formed. Since the sacrificial layer 20 has an etching selectivity with respect to the lower insulating patterns 22, the sacrificial layer 20 may be selectively removed. After the sacrificial layer 20 is removed, the first material layer 24 may be formed to conformally cover the dielectric material layer 16p and the lower insulating patterns 22. The second material layers 26 may be formed on the first material layer 24, and may be disposed between the lower insulating patterns 22. For example, the second material layers 26 may be arranged alternately with the lower insulating patterns 22 in the X-direction. The second material layers 26 may extend in the Y-direction and may be spaced apart from each other in the X-direction. A portion of the first material layer 24 may be exposed without being covered with the second material layers 26.

The first material layer 24 may include silicon oxide, silicon nitride, silicon oxynitride, silicon carbonitride, a low-κ dielectric, or combinations thereof. For example, the first material layer 24 may include silicon oxide. The second material layers 26 may include a material having an etching selectivity with the first material layer 24. For example, the second material layers 26 may include polysilicon.

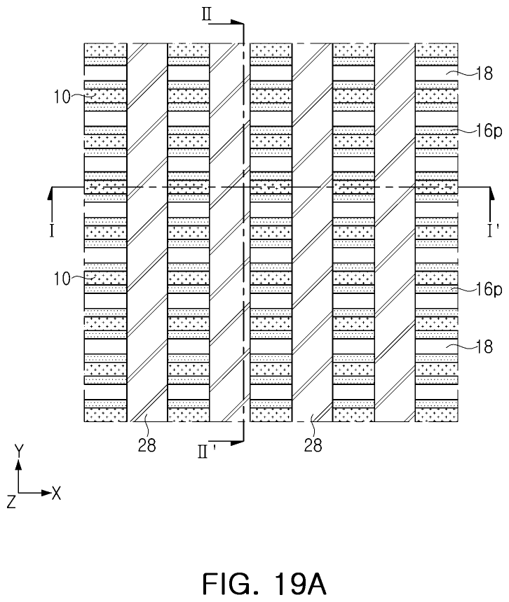

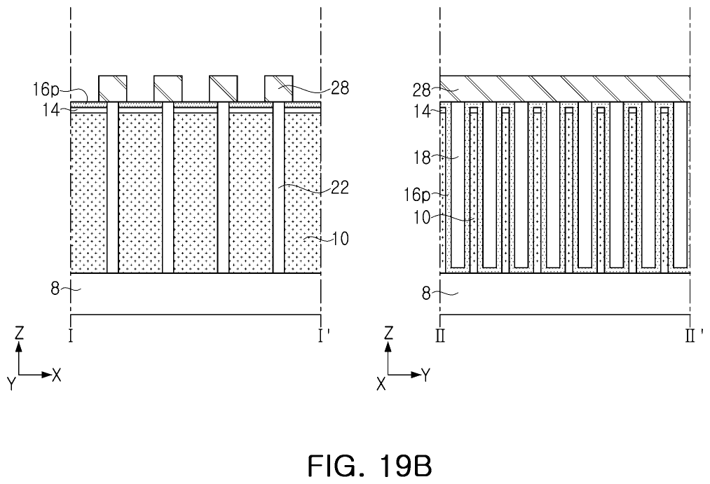

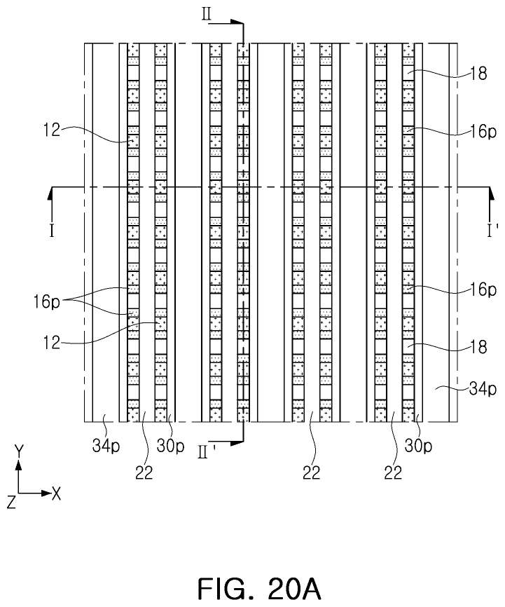

Referring to FIGS. 19A and 19B, portions of the first material layer 24 not covered with the second material layers 26 and upper portions of the lower insulating patterns 22 may be removed, and mask patterns 28 may be formed. For example, the first material layer 24 and the lower insulating patterns 22 may be selectively etched by a wet etching process. After the mask patterns 28 are formed between the second material layers 26, the second material layers 26 may be removed. The remaining first material layer 24 may be completely removed, but the present disclosure is not limited thereto. According to an example embodiment, the first material layer 24 may remain to cover an upper surface of the dielectric material layer 16p. The mask patterns 28 may extend in the Y-direction and may be spaced apart from each other in the X-direction. At least a portion of the mask patterns 28 may overlap the lower insulating patterns 22 in the vertical direction, and a horizontal width of the mask patterns 28 in the X-direction may be greater than a horizontal width of the lower insulating patterns 22 in the X-direction.

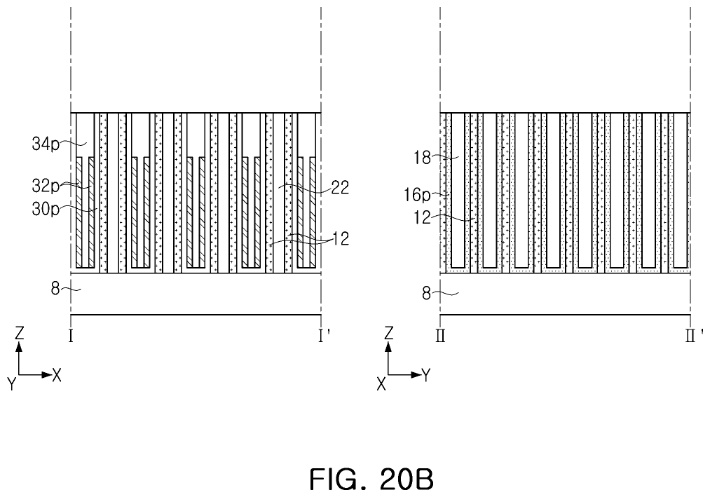

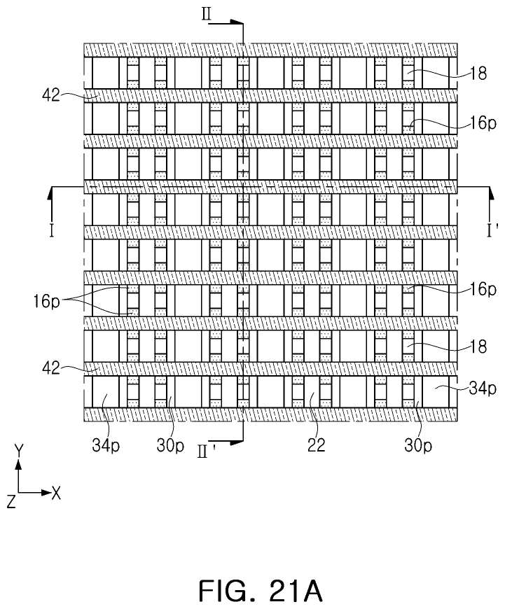

Referring to FIGS. 20A and 20B, the semiconductor patterns 10 may be etched by an anisotropic etching process using the mask patterns 28 as an etching mask to form lower channel patterns 12. The lower channel patterns 12 may extend in the vertical direction and may be spaced apart from each other in the X-direction and the Y-direction. The lower channel patterns 12 may be disposed on both side surfaces of the lower insulating patterns 22.

After the lower channel patterns 12 are formed, dielectric material layers 30p, gate material layers 32p, and insulating material layers 34p may be formed. The dielectric material layers 30p may be formed to cover the insulating layer 8 and the lower channel patterns 12. In a cross-sectional view, the dielectric material layers 30p may have a U shape and may extend in the Y-direction. The gate material layers 32p may be formed by forming a conductive material layer on the dielectric material layers 30p and then etching back the conductive material layer. The gate material layers 32p may extend in the Y-direction and may be spaced apart from each other in the X-direction. The gate material layers 32p may be disposed between the lower channel patterns 12. For example, two gate material layers 32p may be disposed between two lower channel patterns 12 adjacent to each other in the X-direction. The insulating material layers 34p may be formed on the gate material layers 32p. The insulating material layers 34p may cover upper surfaces and side surfaces of the gate material layers 32p. After the insulating material layer 34p is formed, a planarization process may be performed so that upper surfaces of the lower insulating patterns 22 and the lower channel patterns 12 are exposed.

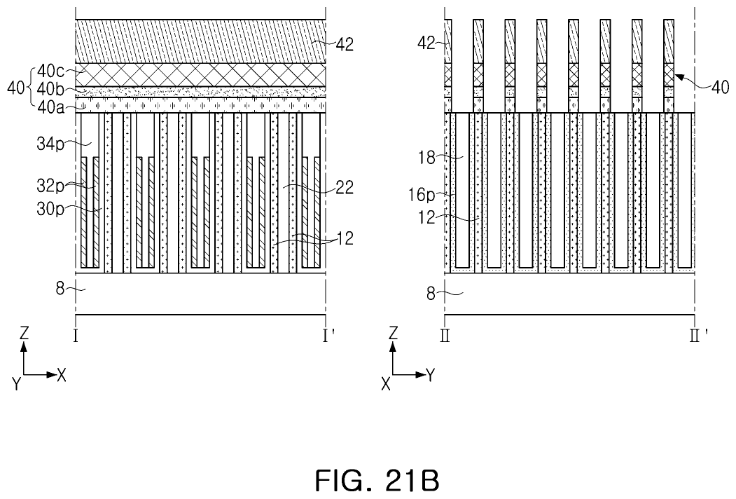

Referring to FIGS. 21A and 21B, bitline structures 40 and capping layers 42 may be formed. Conductive material layers and insulating material layers may be formed to cover the lower channel patterns 12 and the lower sacrificial patterns 18, and the bitline structures 40 and capping layers 42 may be formed by patterning the conductive material layers and insulating material layers.

The bitline structures 40 may be disposed on the lower channel patterns 12, and may extend in the X-direction and be spaced apart from each other in the Y-direction. The bitline structures 40 may be in contact with the lower channel patterns 12 and may be electrically connected thereto. The capping layers 42 may be disposed on the bitline structures 40 and may extend in the X-direction and may be spaced apart from each other in the Y-direction. The lower sacrificial patterns 18 may not be covered with the bitline structures 40 and may be exposed.

The bitline structures 40 may include a first conductive pattern 40a, a second conductive pattern 40b, and a third conductive pattern 40c, which are sequentially stacked. The first conductive pattern 40a may include a semiconductor material such as polycrystalline silicon and may be a layer doped with impurities. The second conductive pattern 40b may include a silicide material, and the third conductive pattern 40c may include a metal material. The capping layers 42 may include silicon nitride.

In an example embodiment, after forming the conductive material layers to cover the lower channel patterns 12 and the lower sacrificial patterns 18 and before forming the bitline structures 40, an annealing process may be performed. By the annealing process, impurities included in the first conductive pattern 40a may be diffused into the lower channel patterns 12, and first source/drain regions 12a (see FIG. 6B) may be formed. According to an example embodiment, the first source/drain regions 12a may be formed by implanting impurities into the lower channel patterns 12 by an ion implantation process. In this case, the first conductive patterns 40a may be omitted, and the upper surfaces of the lower channel patterns 12 may be in contact with the second conductive patterns 40b.

Referring to FIGS. 22A to 22C, spacer structures 44, upper sacrificial patterns 48, a first upper sacrificial layer 50, and a second upper sacrificial layer 51 may be formed. The spacer structures 44 may cover the side surfaces of the bitline structures 40 and the capping layers 42, and may extend in the X-direction. The upper sacrificial patterns 48 may be formed on upper surfaces of the lower sacrificial patterns 18 and side surfaces of the spacer structures 44, and may extend in the X-direction. After the upper sacrificial patterns 48 are formed, a planarization process may be performed so that upper surfaces of the upper sacrificial patterns 48 are coplanar with upper surfaces of the capping layers 42.

The spacer structures 44 may include silicon oxide, silicon nitride, silicon oxynitride, silicon carbonitride, low-κ dielectric or combinations thereof, and may be formed of multiple layers. For example, as illustrated in FIG. 6A, since the spacer structures 44 include a first spacer 45 including silicon nitride, a metal material of the bitline structures 40 may be prevented from being oxidized in subsequent processes.

The first upper sacrificial layer 50 and the second upper sacrificial layer 51 may be sequentially stacked on the capping layers 42 and the upper sacrificial patterns 48. The first upper sacrificial layer 50 may include a material having an etching selectivity with respect to the spacer structures 44 and the second upper sacrificial layer 51, and may include, for example, polysilicon. The second upper sacrificial layer 51 may include silicon nitride.

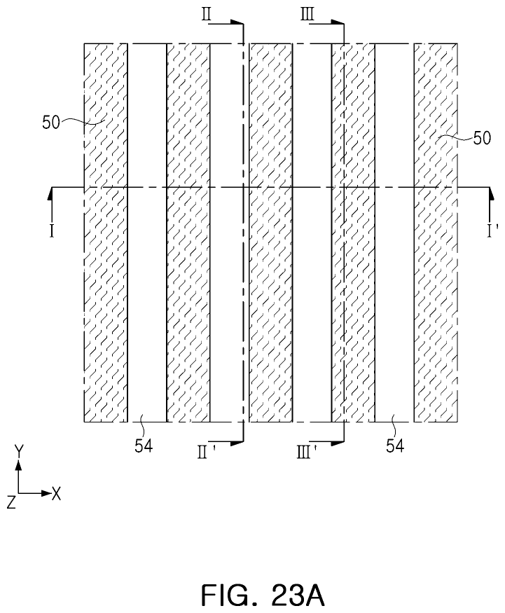

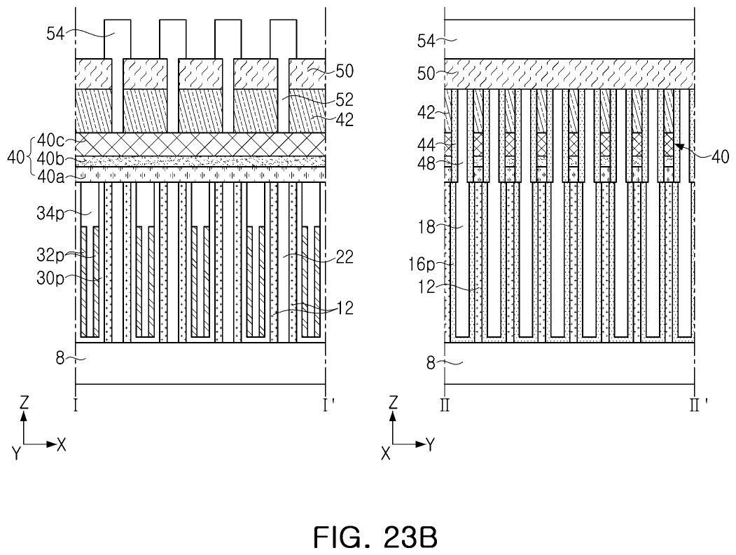

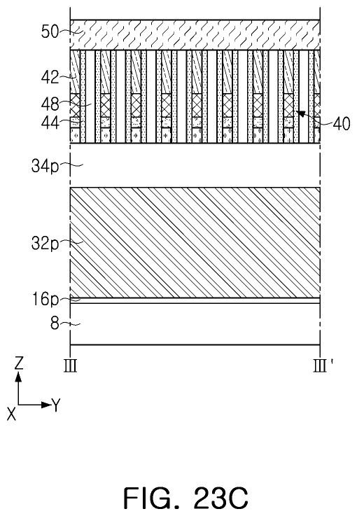

Referring to FIGS. 23A to 23C, upper insulating patterns 52 and mask patterns 54 may be formed. After the capping layers 42, the first upper sacrificial layer 50, and the second upper sacrificial layer 51 are anisotropically etched, the etched portion may be filled with an insulating material layer. After the insulating material layer is formed, the second upper sacrificial layer 51 may be removed, and side surfaces of the insulating material layer may be exposed. An insulating spacer layer may be formed on the side surfaces of the insulating material layer, so that upper insulating patterns 52 and mask patterns 54 may be formed.

A portion of the insulating material layer disposed below an upper surface of the first upper sacrificial layer 50 may be referred to as upper insulating patterns 52. A portion of the insulating material layer disposed above the upper surface of the first upper sacrificial layer 50, and the insulating spacer layer may be referred to as mask patterns 54. The upper insulating patterns 52 and the mask patterns 54 may be formed integrally and may include silicon oxide.

The upper insulating patterns 52 and the mask patterns 54 may extend in the Y-direction and may be spaced apart from each other in the X-direction. At least a portion of the upper insulating patterns 52 may overlap the lower insulating patterns 22 in the vertical direction. A horizontal width of the mask patterns 54 in the X-direction may be larger than a horizontal width of the upper insulating patterns 52 in the X-direction.

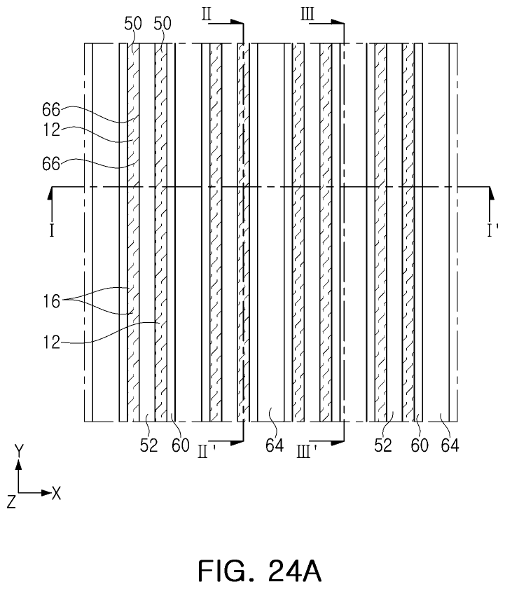

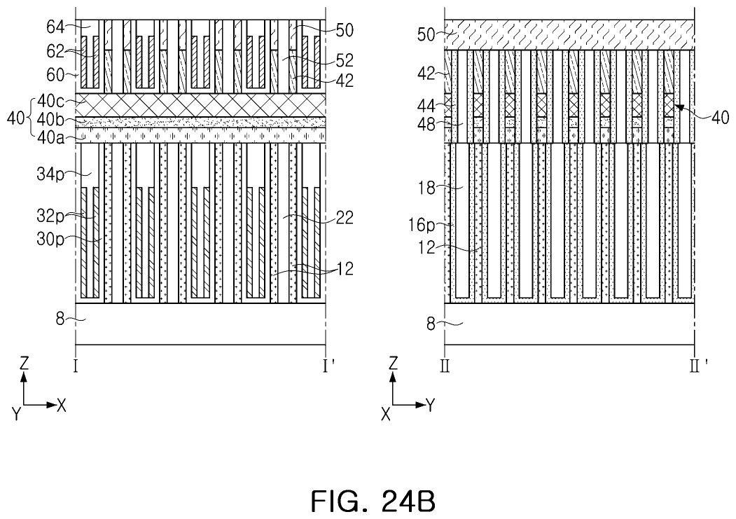

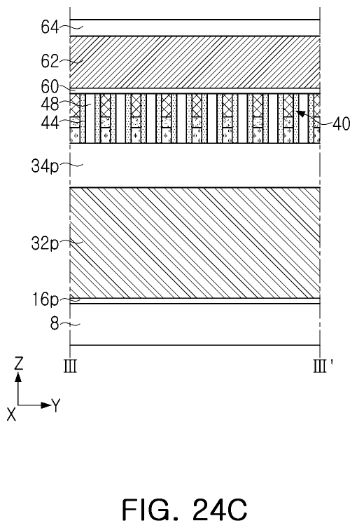

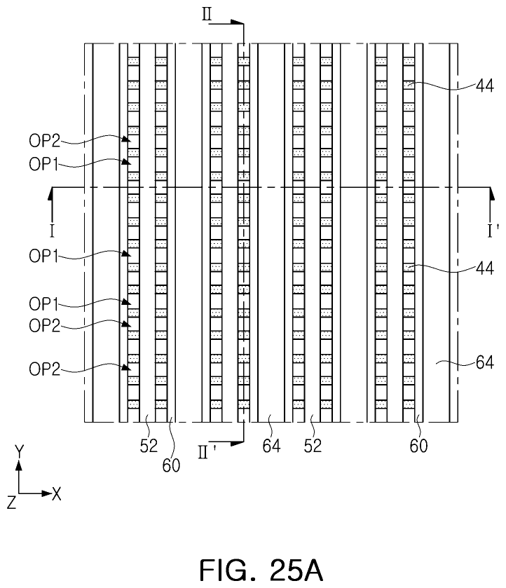

Referring to FIGS. 24A to 24C, the capping layers 42 and the first upper sacrificial layer 50 may be etched by an anisotropic etching process using the mask patterns 54 as an etching mask. The etched capping layers 42 and the first upper sacrificial layer 50 may be disposed on both side surfaces of the upper insulating patterns 52.

Upper gate dielectric layers 60, upper gate electrodes 62, and upper capping layers 64 may be formed. The upper gate dielectric layers 60 may be formed to cover the bitline structures 40, the capping layers 42, and the first upper sacrificial layers 50. In the cross-sectional view, the upper gate dielectric layers 60 may have a U shape and may extend in the Y-direction. The upper gate electrodes 62 may be formed by forming a conductive material layer on the upper gate dielectric layers 60 and then etching back the conductive material layer. The upper gate electrodes 62 may extend in the Y-direction and may be spaced apart from each other in the X-direction. The upper gate electrodes 62 may be disposed between upper insulating patterns 52. For example, two upper gate electrodes 62 may be disposed between two upper insulating patterns 52 adjacent to each other in the X-direction. The upper capping layers 64 may be formed on the upper gate electrodes 62. The upper capping layers 64 may cover upper surfaces and side surfaces of the upper gate electrodes 62. After the upper capping layers 64 are formed, a planarization process may be performed so that the upper surfaces of the upper insulating patterns 52 are exposed.

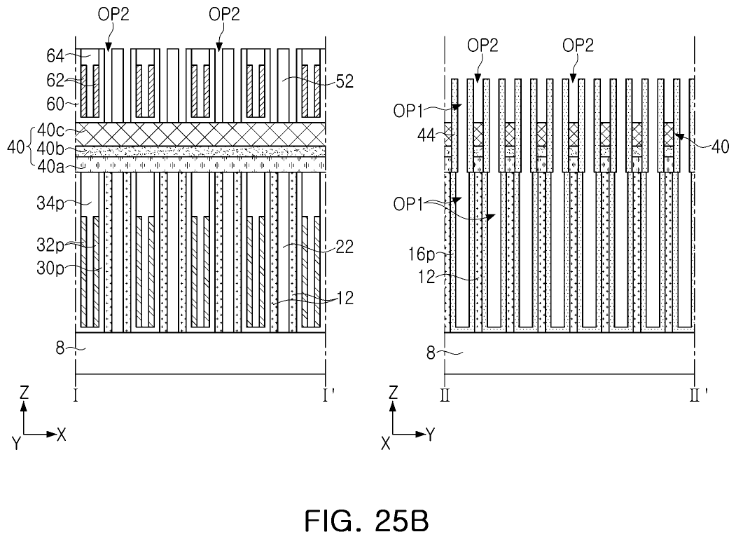

Referring to FIGS. 25A and 25B, the lower sacrificial patterns 18, the upper sacrificial patterns 48, the capping layers 42, and the first upper sacrificial layers 50 may be selectively removed, and first openings OP1 and second openings OP2 may be formed. For example, a space from which the lower sacrificial patterns 18 and the upper sacrificial patterns 48 are removed may be referred to as the first openings OP1. The first openings OP1 may expose the dielectric material layers 16p and the spacer structures 44. A space from which the capping layers 42 and the first upper sacrificial layers 50 are removed may be referred to as the second openings OP2. The second openings OP2 may expose the bitline structures 40, the upper insulating patterns 52, and the upper gate dielectric layers 60. In a plan view, the first openings OP1 and the second openings OP2 may be formed on both side surfaces of the upper insulating patterns 52, and may be formed alternately in the Y-direction.

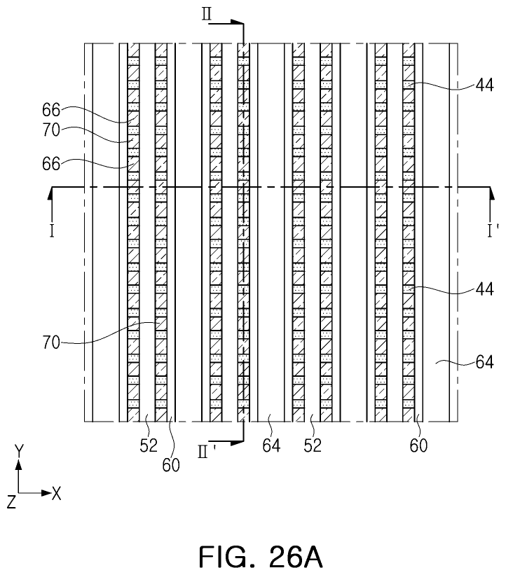

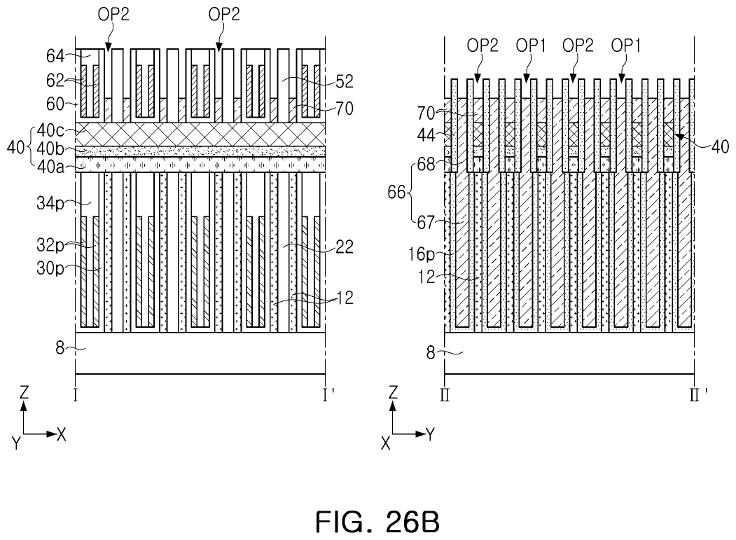

Referring to FIGS. 26A and 26B, charge storage regions 66 and upper conductive layers 70 may be formed. After forming a conductive material layer to fill the first openings OP1 and the second openings OP2 and cover the spacer structures 44, the conductive material layer may be etched back so that at least a portion of the spacer structures 44 is exposed, thus forming charge storage regions 66 and upper conductive layers 70. A portion of the conductive material layer formed within the first openings OP1 may be referred to as charge storage regions 66. Lower portions 67 of the charge storage regions 66 may cover the dielectric material layers 16p, and upper portions 68 of the charge storage regions 66 may cover the side surfaces of the spacer structures 44. The upper surfaces of the upper portions 68 of the charge storage regions 66 may be disposed at a level lower than the upper ends of the spacer structures 44. The lower portions 67 of the charge storage regions 66 may be alternately disposed with the lower channel patterns 12 in the Y-direction.

A portion of the conductive material layer formed within the second openings OP2 may be referred to as upper conductive layers 70. The upper conductive layers 70 may cover the upper surfaces of the bitline structures 40 and the side surfaces of the spacer structures 44. The upper surfaces of the upper conductive layers 70 may be disposed at a level lower than the upper portions of the spacer structures 44. In an example embodiment, the upper surfaces of the upper conductive layers 70 may be disposed at the same level as the upper surfaces of the upper portions 68 of the charge storage regions 66, but the present disclosure is not limited thereto. The charge storage regions 66 and the upper conductive layers 70 may not completely fill the first openings OP1 and the second openings OP2. In a plan view, the charge storage regions 66 and the upper conductive layers 70 may be disposed on both sides of the upper insulating patterns 52 and may be arranged alternately in the Y-direction.

The charge storage regions 66 and the upper conductive layers 70 may include a conductive material. In an example embodiment, the charge storage regions 66 and the upper conductive layers 70 may include a metal material, but the present disclosure is not limited thereto. In an example embodiment, the charge storage regions 66 and the upper conductive layers 70 may include an oxide semiconductor material such as IGZO.

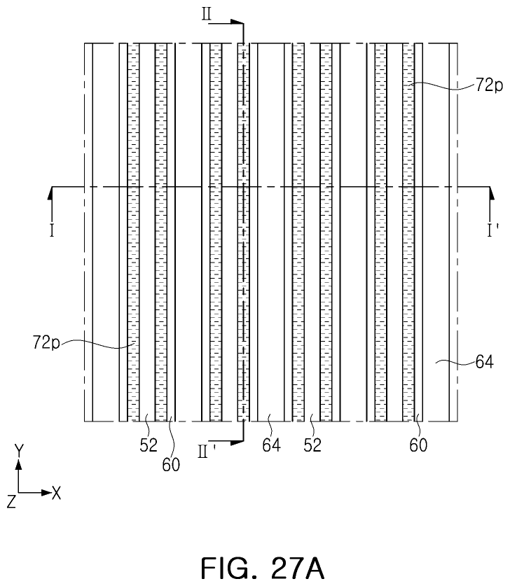

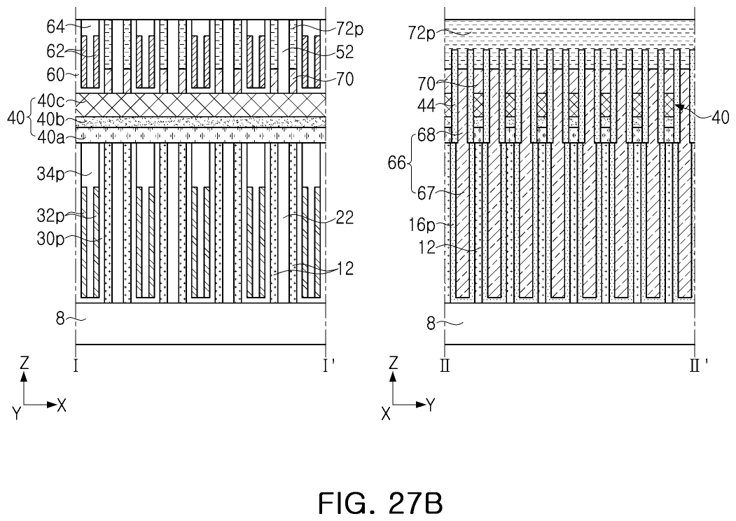

Referring to FIGS. 27A and 27B, a channel material layer 72p may be formed. The channel material layer 72p may fill the first openings OP1 and the second openings OP2, and may be in contact with upper surfaces of the charge storage regions 66 and the upper conductive layers 70. After the channel material layer 72p is formed, a planarization process may be performed so that the upper insulating patterns 52 and the upper capping layers 64 are exposed. The channel material layer 72p may include an oxide semiconductor material such as IGZO.

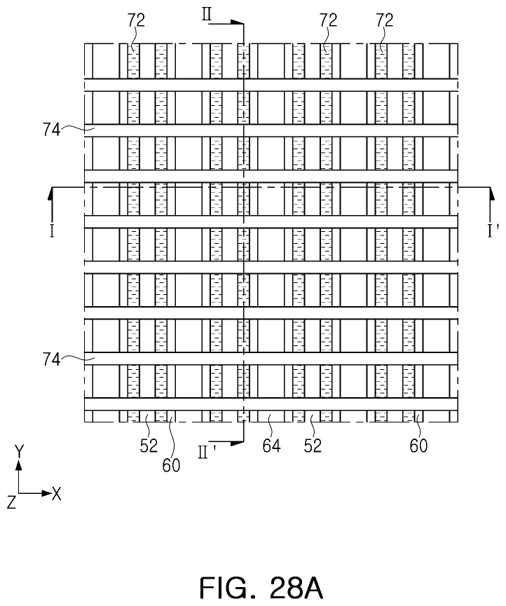

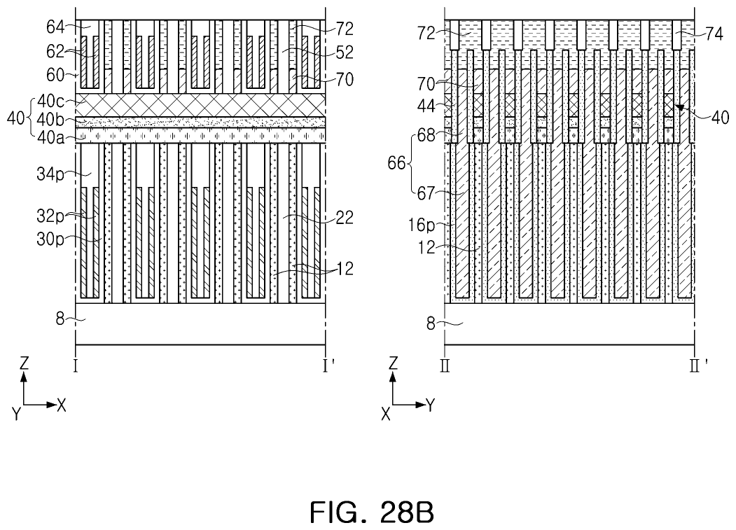

Referring to FIGS. 28A and 28B, the channel material layer 72p may be patterned to form upper channel patterns 72, and insulating structures 74 may be formed between the upper channel patterns 72. The insulating structures 74 may extend in the X-direction and may be spaced apart from each other in the Y-direction. The insulating structures 74 may spatially and electrically isolate the upper channel patterns 72. The insulating structures 74 may extend in the vertical direction from the upper surfaces of the upper channel patterns 72 and may be in contact with upper surfaces of the spacer structures 44. The insulating structures 74 may include, for example, silicon oxide.

The upper channel patterns 72 may be spaced apart from each other in the X-direction and the Y-direction. Each of the upper channel patterns 72 may be in contact with upper surfaces of one charge storage region 66 and one upper conductive layer 70.

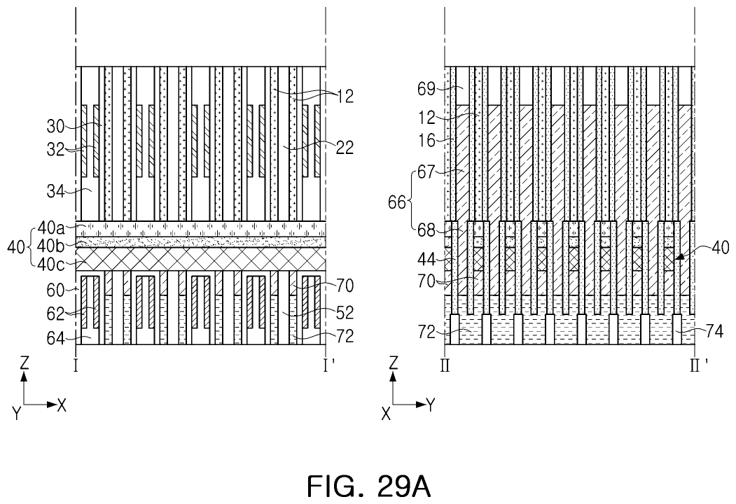

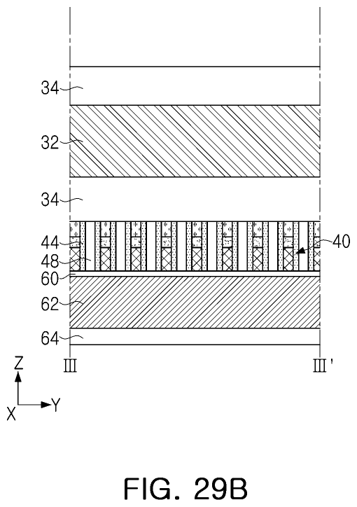

Referring to FIGS. 29A and 29B, the resulting structures of FIGS. 28A and 28B may be flipped over, and the insulating layer 8 may be removed to expose the dielectric material layers 30p. A portion of the dielectric material layers 30p may be removed to expose the gate material layers 32p. The gate material layers 32p may be etched back to form lower gate electrodes 32. The lower portions 67 of the charge storage regions 66 may also be partially etched by an etch-back process. The lower portions 67 of the charge storage regions 66 may be etched simultaneously with the gate material layers 32p, or may be etched by a separate process from a process of etching back the gate material layers 32p.

Insulating material layers may be formed to cover the lower gate electrodes 32 and the lower portions 67 of the charge storage regions 66. The insulating material layers may be formed integrally with the insulating material layers 34p covering the side surfaces of the gate material layers 32p to form a lower capping layer 34. Although the lower capping layer 34 is illustrated as being formed of a single layer in FIG. 29A, the present disclosure is not limited thereto. According to an example embodiment, the lower capping layer 34 may be formed of a plurality of layers. The insulating material layers covering the lower portions 67 of the charge storage regions 66 may be referred to as a lower insulating layer 69.

Referring again to FIGS. 3 to 6C, a conductive structure 80 may be formed to manufacture a semiconductor device 100. The conductive structure 80 may be in contact with the lower channel patterns 12 and may be electrically connected thereto. The conductive structure 80 may include a first conductive layer 80a in contact with the lower channel patterns 12 and a second conductive layer 80b below the first conductive layer 80a.

In an example embodiment, before forming the conductive structure 80, impurities may be implanted into the lower channel patterns 12 by an ion implantation process to form second source/drain regions 12b (see FIG. 6B). In an example embodiment, a polysilicon layer including impurities may be further disposed between the lower channel patterns 12 and the first conductive layer 80a. The impurities included in the polysilicon layer may be diffused into the interior of the lower channel patterns 12 by an annealing process to form second source/drain regions 12b.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A semiconductor device, comprising:
a lower channel pattern extending in a vertical direction;
a lower gate electrode overlapping the lower channel pattern in a first horizontal direction;
an upper channel pattern overlapping the lower channel pattern in the vertical direction;
an upper gate electrode overlapping the upper channel pattern in the first horizontal direction; and
a charge storage region extending in the vertical direction and contacting the upper channel pattern,
wherein the lower channel pattern includes a first source/drain region, a second source/drain region spaced apart from the first source/drain region in the vertical direction, and a channel region between the first source/drain region and the second source/drain region, and
at least a portion of the charge storage region overlaps the lower channel pattern in a second horizontal direction, intersecting the first horizontal direction.

2. The semiconductor device of claim 1, wherein a lower portion of the charge storage region is adjacent to a side surface of the lower channel pattern, and
an upper portion of the charge storage region is in contact with the upper channel pattern.

3. The semiconductor device of claim 2, wherein a horizontal width of the lower portion of the charge storage region is different from a horizontal width of the upper portion of the charge storage region.

4. The semiconductor device of claim 2, wherein the upper portion of the charge storage region overlaps the upper gate electrode in the first horizontal direction.

5. The semiconductor device of claim 1, further comprising:
a bitline structure between the lower channel pattern and the upper channel pattern,
wherein the bitline structure is in contact with an upper surface of the lower channel pattern.

6. The semiconductor device of claim 5, further comprising:
an upper conductive layer in contact with an upper surface of the bitline structure and a lower surface of the upper channel pattern,
wherein an upper surface of the upper conductive layer is disposed at the same level as an upper surface of the charge storage region.

7. The semiconductor device of claim 5, further comprising:
a spacer structure covering a side surface of the bitline structure and disposed between the charge storage region and the bitline structure,
wherein an upper end of the spacer structure is disposed at a higher level than an upper surface of the bitline structure.

8. The semiconductor device of claim 7, wherein the upper channel pattern includes a first lower portion in contact with the charge storage region and a second lower portion overlapping the bitline structure in the vertical direction, and
the first lower portion is spaced apart from the second lower portion with the spacer structure interposed therebetween.

9. The semiconductor device of claim 1, wherein the lower channel pattern includes a different material from the upper channel pattern.

10. The semiconductor device of claim 1, wherein the charge storage region includes a material different from the upper channel pattern.

11. The semiconductor device of claim 1, wherein a vertical length of the lower gate electrode varies depending on a distance from a side surface of the lower channel pattern.

12. The semiconductor device of claim 1, further comprising:
a conductive layer disposed on at least one of a lower surface or an upper surface of the lower gate electrode and including a different material from the lower gate electrode.

13. The semiconductor device of claim 11, wherein the charge storage region includes the same material as the upper channel pattern and is formed integrally with the upper channel pattern.

14. A semiconductor device, comprising:
lower channel patterns extending in a vertical direction and spaced apart from each other in a first horizontal direction;
a lower gate electrode adjacent to the lower channel patterns in a second horizontal direction, intersecting the first horizontal direction, and extending in the first horizontal direction;
upper channel patterns overlapping the lower channel patterns in the vertical direction;
an upper gate electrode adjacent to the upper channel patterns in the second horizontal direction and extending in the first horizontal direction; and
charge storage regions extending in the vertical direction and contacting lower surfaces of the upper channel patterns,
wherein lower portions of the charge storage regions are alternately disposed with the lower channel patterns in the first horizontal direction.

15. The semiconductor device of claim 14, further comprising:
bitline structures extending in the second horizontal direction between the lower channel patterns and the upper channel patterns,
wherein the bitline structures are in contact with upper surfaces of the lower channel patterns.

16. The semiconductor device of claim 15, wherein upper portions of the charge storage regions are alternately disposed with the bitline structures in the first horizontal direction.

17. The semiconductor device of claim 15, further comprising:
upper conductive layers alternately disposed with upper portions of the charge storage regions in the first horizontal direction,
wherein the upper conductive layers are in contact with upper surfaces of the bitline structures and lower surfaces of the upper channel patterns.

18. The semiconductor device of claim 14, further comprising:
dielectric patterns between the lower channel patterns and the charge storage regions.

19. The semiconductor device of claim 14, wherein the charge storage regions include a first charge storage region and a second charge storage region adjacent to each other in the first horizontal direction, and
a lower channel pattern between the first charge storage region and the second charge storage region, among the lower channel patterns, is disposed closer to the first charge storage region than to the second charge storage region.

20. A semiconductor device, comprising:
a lower channel pattern extending in a vertical direction;
a conductive structure in contact with a lower surface of the lower channel pattern; a lower gate electrode overlapping the lower channel pattern in a first horizontal direction;
an upper channel pattern overlapping the lower channel pattern in the vertical direction;
a bitline structure between the lower channel pattern and the upper channel pattern;
an upper gate electrode overlapping the upper channel pattern in the first horizontal direction;
a charge storage region extending in the vertical direction and contacting the upper channel pattern;
a dielectric pattern between a lower portion of the charge storage region and the lower channel pattern; and
a spacer structure between an upper portion of the charge storage region and the bitline structure,
wherein at least a portion of the charge storage region overlaps the lower channel pattern in a second horizontal direction, intersecting the first horizontal direction.
